(19) United States
(12) Patent Application Publication
(10) Pub. No.: US 2026/0328557 A1
(43) Pub. Date: Oct. 22, 2026

(54) Method for Atomic Scale Processing Optimization by In Situ Ellipsometry

(71) Applicant: Kurt J. Lesker Company, Jefferson Hills, PA (US)

(72) Inventors: Gilbert Bruce Rayner, Jr., Spring Mills, PA (US); Noel Christopher O'Toole, Aliquippa, PA (US)

(21) Appl. No.: 19/372,598

(22) Filed: Oct. 29, 2025

Related U.S. Application Data
(60) Provisional application No. 63/713,198, filed on Oct. 29, 2024.

(51) Int. Cl. G01B 11/06; C23C 16/455

(52) U.S. Cl. CPC G01B 11/0641; C23C 16/45536

(57) ABSTRACT

A method of optimizing atomic scale processing of a coated and/or etched substrate includes: providing a substrate; subjecting the substrate to atomic scale processing to produce a coated and/or etched substrate; subjecting the coated and/or etched substrate to ellipsometry, including: directing a beam of light with a wavelength at a surface of the coated and/or etched substrate; polarizing the beam of light to obtain polarized light; measuring a change in polarization of the polarized light after the polarized light reflects off of the surface of the coated and/or etched substrate to obtain sample polarization data; and determining a film thickness and/or an optical property of the coated and/or etched substrate by comparing the sample polarization data to an ellipsometric model; and adjusting the atomic scale processing based on the determined film thickness and/or the determined optical property.

### CROSS REFERENCE TO RELATED APPLICATION

This application claims the benefit of U.S. Provisional Application No. 63/713,198, filed Oct. 29, 2024, the disclosure of which is hereby incorporated by reference in its entirety.

### BACKGROUND OF THE INVENTION

### Field of the Invention

The present disclosure is directed to atomic scale processing and, more particularly, to methods and/or apparatuses for optimizing atomic scale processing by in situ ellipsometry.

### Description of Related Art

Atomic scale processing (ASP) techniques are of considerable interest for a wide range of electronic applications including logic, memory, power and optoelectronic devices. ASP includes purely thermal and plasma-enhanced techniques for atomic layer deposition (ALD), atomic layer etching (ALE), and area selective ALD (ASALD), which are based on sequential deposition (ALD/ASALD) and/or removal (ALE) of material with atomic scale precision and control. Due to the surface-controlled nature of atomic scale processing, maintaining a consistent, highly controlled environment is necessary for achieving consistent, reproducible process results.

ALD is a chemical vapor deposition (CVD) technique based on sequential, self-limiting surface reactions between gas/vapor phase species and active surface sites. The unique surface-controlled nature of ALD make it an ideal choice for demanding applications requiring conformal, high-quality oxide and non-oxide based materials, as well as their interfaces. For example, gate stack fabrication (i.e., high-k dielectric and metal gate) by ALD techniques for three-dimensional (3D) gate-all-around field effect transistor (GAAFET) device architectures for sub-10 nm technology nodes. ALD techniques include purely thermal and plasma enhanced ALD (PEALD). A limitation associated with current PEALD reactor designs is the undesirable incorporation of oxygen during growth of non-oxide based materials, especially materials with a high affinity for oxygen, such as titanium nitride (TiNₓ), aluminum nitride (AlNₓ), silicon nitride (SiNₓ), aluminum (Al), Titanium (Ti), tantalum (Ta), and the like. Due to the relatively slow deposition rates of materials grown by PEALD, non-oxide processes have long suffered from high exposures to background oxygen impurities, such as O₂ and/or H₂O, during growth yielding elevated levels of oxygen impurities in the resulting layers.

ALE is another atomic scale processing technique that benefits from UHP conditions. Unlike ALD techniques which are based on layer-by-layer growth, ALE techniques remove (or etch) material one layer at a time. More specifically, ALE techniques remove thin-modified surface layers with atomic scale control. At present, ALE is primarily motivated by limitations of traditional reactive ion etch (RIE) techniques for technology nodes below 10 nm. In addition to the use of ALE for defining critical device structures and patterning, a combination of ALD/PEALD and ALE techniques has been shown to effectively reduce surface roughness through growth and subsequent etch steps. For example, nucleation delay during the initial stages of growth can result in 3D island formation which leads to high surface roughness, as well as the inability to grow thin, continuous layers. Through a series of growth and etch steps, however, extremely smooth, thin, continuous layers can be achieved.

ASALD is an ALD technique that takes advantage of differences in precursor reactivity between different starting surfaces to enable selective growth. ASALD is a bottom-up approach enabling self-alignment of features during growth thereby addressing edge placement errors associated with traditional patterning techniques. Ideally, deposition would only occur on designated growth areas, but this is frequently not the case, such that ASALD often requires a combination of ALD/PEALD and ALE process steps to ensure the desired selectivity.

Typically, an ASP technique is modified and optimized based on the specific precursors used, in combination with investigating various parameters used to deposit and/or remove material after the process has been completed. For example, the properties of a film can be determined after a coated and/or etched substrate has been formed by the ASP apparatus and removed from the ASP apparatus so that processing parameters can be adjusted when another coated and/or etched substrate is formed. However, there currently is a need for an improved method or apparatus that allows for optimization of the atomic scale processing of a coated and/or etched substrate in situ during the formation of material on, and/or removal of material from, the surface of a substrate.

Therefore, an in situ method of optimization during the atomic scale processing of a coated and/or etched substrate is desirable. Additionally, an atomic scale processing apparatus that is configured to optimize atomic scale processing of a coated and/or etched substrate in situ during atomic scale processing is also desirable.

### SUMMARY OF THE INVENTION

In view of the foregoing, there is a current need in the art for an in situ method of optimizing and/or monitoring atomic scale processing of a substrate. In further view of the foregoing, there is a current need in the art for an atomic scale processing apparatus that can optimize and/or monitor in situ the atomic scale processing of the substrate.

In one non-limiting example of the present disclosure, a method of optimizing atomic scale processing of a coated and/or etched substrate includes: providing a substrate; subjecting the substrate to atomic scale processing to produce a coated and/or etched substrate, including: dosing the substrate with a precursor; subjecting the coated and/or etched substrate to ellipsometry, including: directing a beam of light with a wavelength at a surface of the coated and/or etched substrate; polarizing the beam of light to obtain polarized light; measuring a change in polarization of the polarized light after the polarized light reflects off of the surface of the coated and/or etched substrate to obtain sample polarization data; and determining a film thickness and/or an optical property of the coated and/or etched substrate by comparing the sample polarization data to an ellipsometric model; and adjusting the atomic scale processing based on the determined film thickness and/or the determined optical property, including: adjusting the dosing of the precursor based on the determined film thickness and/or the determined optical property.

The optical property may be refractive index, extinction coefficient, optical bandgap, optical resistivity, optical conductivity, or a combination thereof. The atomic scale processing may be plasma-enhanced atomic layer deposition or thermal atomic layer deposition. The atomic scale processing may be plasma-enhanced atomic layer etching or thermal atomic layer etching. The ellipsometric model may be a three-layer ellipsometric model comprising a silicon substrate, a native oxide layer over the silicon substrate, and a Cauchy layer over the native oxide layer. The coated and/or etched substrate may include the substrate, and a film on the surface of the substrate. The method may further include: providing the substrate on a fixture assembly in an internal volume of a reactor; and subjecting the substrate to the atomic scale processing, including: dosing the surface of the substrate with a first precursor; purging the remaining first precursor and/or reaction byproducts from the internal volume of the reactor; dosing the surface of the substrate with the second precursor; and purging the remaining second precursor and/or reaction byproducts from the internal volume of the reactor. The substrate may include silicon, germanium, sapphire, magnesium oxide, boron nitride, aluminum nitride, gallium nitride, or indium nitride. The substrate may also include one or more layers on the surface. The method may further include: purging the remaining first precursor and/or reaction byproducts and/or the remaining second precursor and/or reaction byproducts from the internal volume of the reactor while subjecting the coated and/or etched substrate to ellipsometry. The method may further include: dosing the first precursor and/or the second precursor while subjecting the coated and/or etched substrate to ellipsometry. The ellipsometry may be single wavelength ellipsometry, or may be discrete multiwavelength ellipsometry or spectroscopic ellipsometry further including directing the beam of light with a plurality of wavelengths at the surface of the substrate. The method may further include: performing the atomic scale processing at room temperature, or heating the substrate to a temperature in the range of from 50° C. to 400° C. The method may further include: subjecting the coated and/or etched substrate to ellipsometry while the coated and/or etched substrate is in an atomic scale processing reactor.

In another non-limiting example of the present disclosure, an atomic scale processing apparatus, includes: a reactor having inner and outer surfaces, where at least a portion of the inner surfaces define an internal volume of the reactor; a fixture assembly positioned within the internal volume of the reactor having a surface configured to hold a coated and/or etched substrate within the internal volume of the reactor; a first precursor delivery arrangement comprising a first precursor; a second precursor delivery arrangement comprising a second precursor; and an ellipsometer capable of obtaining a film thickness and/or an optical property of the coated and/or etched substrate while the coated and/or etched substrate is in the internal volume of the reactor.

The atomic scale processing apparatus may further include: a controller configured to optimize atomic scale processing of the coated and/or etched substrate by carrying out a series of process parameter adjustments and obtaining a plurality of film thickness values and/or optical property values from the ellipsometer for each process parameter adjustment, the plurality of film thickness values and/or optical property values forming a saturation behavior of film growth, comparing the saturation behavior at each process parameter value to a threshold, and adjusting the process parameter during the atomic scale processing to the process parameter value with a saturation behavior that satisfies the threshold. The ellipsometer may be a single or discrete multiwavelength ellipsometer or a spectroscopic ellipsometer. The second precursor delivery arrangement may be an inductively coupled plasma source, and where the second precursor comprises plasma. A temperature of the internal volume of the reactor may be in the range of from room temperature to 400° C.

In another non-limiting example of the present disclosure, a method of optimizing atomic scale processing of a coated and/or etched substrate includes: providing a substrate in an internal volume of a reactor; subjecting the substrate to atomic scale processing to produce a coated and/or etched substrate including: dosing the substrate with a precursor; and purging the remaining precursor and/or reaction byproducts from the internal volume of the reactor; subjecting the coated and/or etched substrate to ellipsometry, including: directing a beam of light with a wavelength at a surface of the coated and/or etched substrate; polarizing the beam of light to obtain polarized light; measuring a change in polarization of the polarized light after the polarized light reflects off of the surface of the coated and/or etched substrate to obtain sample polarization data; and determining a film thickness and/or an optical property of the coated and/or etched substrate by comparing the sample polarization data to an ellipsometric model; and adjusting the atomic scale processing based on the determined film thickness and/or the determined optical property, including: adjusting the purging of the remaining precursor and/or reaction byproducts from the internal volume of the reactor based on the determined film thickness and/or the determined optical property.

The subjecting the substrate to the atomic scale processing may include: dosing the surface of the substrate with a first precursor; purging the remaining first precursor and/or reaction byproducts from the internal volume of the reactor; dosing the surface of the substrate with the second precursor; and purging the remaining second precursor and/or reaction byproducts from the internal volume of the reactor. The adjusting the atomic scale processing may include: adjusting the purging of the remaining first precursor and/or reaction byproducts and/or the remaining second precursor and/or reaction byproducts from the internal volume of the reactor based on the determined film thickness and/or the determined optical property.

Various non-limiting examples of the present disclosure will now be described and set forth in the following numbered clauses.

Clause 1: A method of optimizing atomic scale processing of a coated and/or etched substrate, comprising: providing a substrate; subjecting the substrate to atomic scale processing to produce a coated and/or etched substrate, comprising: dosing the substrate with a precursor; subjecting the coated and/or etched substrate to ellipsometry, comprising: directing a beam of light with a wavelength at a surface of the coated and/or etched substrate; polarizing the beam of light to obtain polarized light; measuring a change in polarization of the polarized light after the polarized light reflects off of the surface of the coated and/or etched substrate to obtain sample polarization data; and determining a film thickness and/or an optical property of the coated and/or etched substrate by comparing the sample polarization data to an ellipsometric model; and adjusting the atomic scale processing based on the determined film thickness and/or the determined optical property, comprising: adjusting the dosing of the precursor based on the determined film thickness and/or the determined optical property.

Clause 2: The method of clause 1, wherein the optical property is refractive index, extinction coefficient, optical bandgap, optical resistivity, conductivity, or a combination thereof.

Clause 3: The method of clause 1 or clause 2, wherein the atomic scale processing is plasma-enhanced atomic layer deposition, plasma-enhanced atomic layer etching, thermal atomic layer deposition, or thermal atomic layer etching.

Clause 4: The method of any one of clauses 1-3, wherein the ellipsometric model is a three-layer ellipsometric model comprising a silicon substrate, a native oxide layer over the silicon substrate, and a Cauchy layer over the native oxide layer.

Clause 5: The method of any one of clauses 1-4, wherein the coated and/or etched substrate comprises the substrate, and a film on the surface of the substrate.

Clause 6: The method of any one of clauses 1-5, further comprising: providing the substrate on a fixture assembly in an internal volume of a reactor; and subjecting the substrate to the atomic scale processing, comprising: dosing the surface of the substrate with a first precursor; purging the remaining first precursor and/or reaction byproducts from the internal volume of the reactor; dosing the surface of the substrate with the second precursor; and purging the remaining second precursor and/or reaction byproducts from the internal volume of the reactor.

Clause 7: The method of any one of clauses 1-6, wherein the substrate comprises silicon, germanium, sapphire, magnesium oxide, boron nitride, aluminum nitride, gallium nitride, or indium nitride.

Clause 8: The method of clause 6, further comprising purging the remaining first precursor and/or reaction byproducts and/or the remaining second precursor and/or reaction byproducts from the internal volume of the reactor while subjecting the coated and/or etched substrate to ellipsometry.

Clause 9: The method of clause 6, further comprising dosing the first precursor and/or the second precursor while subjecting the coated and/or etched substrate to ellipsometry.

Clause 10: The method of any one of clauses 1-9, wherein the ellipsometry is single wavelength ellipsometry, or the ellipsometry is multiwavelength ellipsometry or spectroscopic ellipsometry and further comprising directing the beam of light with a plurality of wavelengths at the surface of the substrate.

Clause 11: The method of any one of clauses 1-10, further comprising: performing the atomic scale processing at room temperature, or heating the substrate to a temperature in the range of from 50° C. to 400° C.

Clause 12: The method of any one of clauses 1-11, further comprising subjecting the coated and/or etched substrate to ellipsometry while the coated and/or etched substrate is in an atomic scale processing reactor.

Clause 13: An atomic scale processing apparatus, comprising: a reactor having inner and outer surfaces, wherein at least a portion of the inner surfaces define an internal volume of the reactor; a fixture assembly positioned within the internal volume of the reactor having a surface configured to hold a coated and/or etched substrate within the internal volume of the reactor; a first precursor delivery arrangement comprising a first precursor; a second precursor delivery arrangement comprising a second precursor; and an ellipsometer capable of obtaining a film thickness and/or an optical property of the coated and/or etched substrate while the coated and/or etched substrate is in the internal volume of the reactor.

Clause 14: The atomic scale processing apparatus of clause 13, further comprising: a controller configured to optimize atomic scale processing of the coated and/or etched substrate by carrying out a series of process parameter adjustments and obtaining a plurality of film thickness values and/or optical property values from the ellipsometer for each process parameter adjustment, the plurality of film thickness values and/or optical property values forming a saturation behavior of film growth, comparing the saturation behavior at each process parameter value to a threshold, and adjusting the process parameter during the atomic scale processing to the process parameter value with a saturation behavior that satisfies the threshold.

Clause 15: The atomic scale processing apparatus of clause 13 or clause 14, wherein the ellipsometer is a single or a discrete multiwavelength ellipsometer or a spectroscopic ellipsometer.

Clause 16: The atomic scale processing apparatus of any one of clauses 13-15, wherein the second precursor delivery arrangement is an inductively coupled plasma source, and wherein the second precursor comprises plasma.

Clause 17: The atomic scale processing apparatus of any one of clauses 13-16, wherein a temperature of the internal volume of the reactor is in the range of from room temperature to 400° C.

Clause 18: A method of optimizing atomic scale processing of a coated and/or etched substrate, comprising: providing a substrate in an internal volume of a reactor; subjecting the substrate to atomic scale processing to produce a coated and/or etched substrate, comprising: dosing the substrate with a precursor; and purging the remaining precursor and/or reaction byproducts from the internal volume of the reactor; subjecting the coated and/or etched substrate to ellipsometry, comprising: directing a beam of light with a wavelength at a surface of the coated and/or etched substrate; polarizing the beam of light to obtain polarized light; measuring a change in polarization of the polarized light after the polarized light reflects off of the surface of the coated and/or etched substrate to obtain sample polarization data; and determining a film thickness and/or an optical property of the coated and/or etched substrate by comparing the sample polarization data to an ellipsometric model; and adjusting the atomic scale processing based on the determined film thickness and/or the determined optical property, comprising: adjusting the purging of the precursor from the internal volume of the reactor based on the determined film thickness and/or the determined optical property.

Clause 19: The method of clause 18, wherein the subjecting the substrate to the atomic scale processing comprises: dosing the surface of the substrate with a first precursor; purging the remaining first precursor and/or reaction byproducts from the internal volume of the reactor; dosing the surface of the substrate with the second precursor; and purging the remaining second precursor and/or reaction byproducts from the internal volume of the reactor.

Clause 20: The method of clause 19, wherein the adjusting the atomic scale processing comprises: adjusting the purging of the remaining first precursor and/or reaction byproducts and/or the remaining second precursor and/or reaction byproducts from the internal volume of the reactor based on the determined film thickness and/or the determined optical property.

### BRIEF DESCRIPTION OF THE DRAWINGS

FIG. 1 is a diagram of a method according to one aspect of the present disclosure;

FIG. 2 is a cross-sectional view of a reactor for atomic scale processing according to another aspect of the present disclosure;

FIG. 3 is a cross-sectional view of an inductively coupled plasma source according to another aspect of the present disclosure;

FIG. 4 is a perspective view of an apparatus for atomic scale processing according to another aspect of the present disclosure;

FIG. 5 is a perspective view of an apparatus for atomic scale processing according to another aspect of the present disclosure;

FIG. 6A is a perspective view of a precursor/reactant vapor delivery arrangement according to another aspect of the present disclosure;

FIG. 6B is a perspective view of a precursor/reactant vapor delivery arrangement according to another aspect of the present disclosure;

FIG. 6C is a schematic of a mass flow controller (MFC) arrangement for implementing with any of the precursor/reactant vapor delivery arrangements disclosed herein according to another aspect of the present disclosure;

FIG. 7 is a cross-sectional view of a reactor for atomic scale processing according to another aspect of the present disclosure;

FIG. 8 is a diagram of a reactor control system according to another aspect of the present disclosure;

FIG. 9 is a diagram of components of a controller according to another aspect of the present disclosure;

FIG. 10 is a diagram of a process to be performed by a controller according to another aspect of the present disclosure;

FIG. 11A is a graph of ScN thickness vs. time measured in real-time by multiwavelength ellipsometry (MWE) during growth for a series of 30 PEALD cycles;

FIG. 11B is a graph of a 30-cycle growth profile of ScN thickness vs. time measured in real-time by multiwavelength ellipsometry (MWE) during growth;

FIG. 11C is a graph of the general features of the PEALD ScN step profile of ScN thickness vs. time measured in real-time by multiwavelength ellipsometry (MWE) during growth;

FIG. 12A is a graph of ScN growth-per-cycle (GPC) vs. ClSc(EtCp)₂ dose time at substrate temperatures ranging from 200-300° C.;

FIG. 12B is a graph of ScN growth-per-cycle (GPC) vs. N₂—H₂ plasma dose time at 215° C. substrate temperature;

FIG. 12C is a graph of ScN growth-per-cycle (GPC) vs. substrate temperature;

FIG. 13A is a graph of ScN growth-per-cycle (GPC) average & thickness non-uniformity (NU) vs. N₂—H₂ plasma dose time at 215° C. substrate temperature;

FIG. 13B is a graph of ScN growth-per-cycle (GPC) average and at the center of the substrate vs. N₂—H₂ plasma dose time;

FIG. 14A is a graph of ScN growth-per-cycle (GPC) vs. ClSc(EtCp)₂ dose time at 215° C. substrate temperature before and after thermally cycling the Sc precursor between room temperature and 180° C.;

FIG. 14B is a graph of ScN growth-per-cycle (GPC) vs. ClSc(EtCp)₂ purge time;

FIG. 14C is a graph of ScN growth-per-cycle (GPC) vs. N₂—H₂ plasma purge time;

FIG. 14D is a graph of ScN growth-per-cycle (GPC) vs. ClSc(EtCp)₂ dose and purge times;

FIG. 15A is a graph of ellipsometric data for thin and thick ScN films at the center and edge of the wafer;

FIG. 15B is a graph of ScN optical constants determined at the center and edge positions of 150 mm Si substrates;

FIG. 16 is a graph of a x-ray photoelectron spectroscopy (XPS) depth profile for ScN showing the concentration vs. sputter depth of all major and minor elemental components of the film;

FIG. 17A is a graph of grazing incidence x-ray diffraction (GIXRD) patterns for ScN on 150 mm Si (100) at center and edge positions;

FIG. 17B is a graph of grazing incidence x-ray diffraction (GIXRD) patterns for ScN on Al₂O₃ (0001);

FIG. 17C is a graph of grazing incidence x-ray diffraction (GIXRD) patterns for ScN on MgO (001);

FIG. 18 is a graph of grazing incidence x-ray diffraction (GIXRD) patterns for ScN #2 measured at the center of the 150 mm Si (100) substrate;

FIG. 19 is a graph of x-ray diffraction (XRD) interference patterns observed for the ScN (111) peak measured on c-plane α-Al₂O₃ substrate;

FIG. 20A are graphs of phi-scans for ScN on Al₂O₃ (0001);

FIG. 20B are graphs of phi-scans for ScN on MgO (001);

FIG. 21A is a field emission scanning electron microscopy (FESEM) image of a top view of ScN #2;

FIG. 21B is a field emission scanning electron microscopy (FESEM) image of a cross-sectional view of ScN #2;

FIG. 21C is an image of ScN-coated trenches with a 4:1 aspect ratio imaged by field emission scanning electron microscopy (FESEM); and

FIG. 21D is an image of a cross-sectional view of ScN-coated trenches with 4:1 aspect ratio imaged by field emission scanning electron microscopy (FESEM).

### DESCRIPTION OF THE INVENTION

For purposes of the description hereinafter, spatial orientation terms, as used, shall relate to the referenced embodiment as it is oriented in the accompanying drawings, figures, or otherwise described in the following detailed description. However, it is to be understood that the embodiments described hereinafter may assume many alternative variations and configurations. It is also to be understood that the specific components, devices, features, and operational sequences illustrated in the accompanying drawings, figures, or otherwise described herein are simply exemplary and should not be considered as limiting.

For purposes of the description hereinafter, the terms “upper,” “lower,” “right,” “left,” “vertical,” “horizontal,” “top,” “bottom,” “lateral,” “longitudinal,” and derivatives thereof shall relate to the invention as it is oriented in the drawing figures. However, it is to be understood that the invention may assume alternative variations and step sequences, except where expressly specified to the contrary. It is also to be understood that the specific devices and processes illustrated in the attached drawings, and described in the following specification, are simply exemplary embodiments of the invention. Hence, specific dimensions and other physical characteristics related to the embodiments disclosed herein are not to be considered as limiting.

Also, it should be understood that any numerical range recited herein is intended to include all sub-ranges subsumed therein. For example, a range of “1 to 10” is intended to include all sub-ranges between (and including) the recited minimum value of 1 and the recited maximum value of 10, that is, having a minimum value equal to or greater than 1 and a maximum value of equal to or less than 10.

In this application, the use of the singular includes the plural and plural encompasses singular, unless specifically stated otherwise. In addition, in this application, the use of “or” means “and/or” unless specifically stated otherwise, even though “and/or” may be explicitly used in certain instances. Further, in this application, the use of “a” or “an” means “at least one” unless specifically stated otherwise.

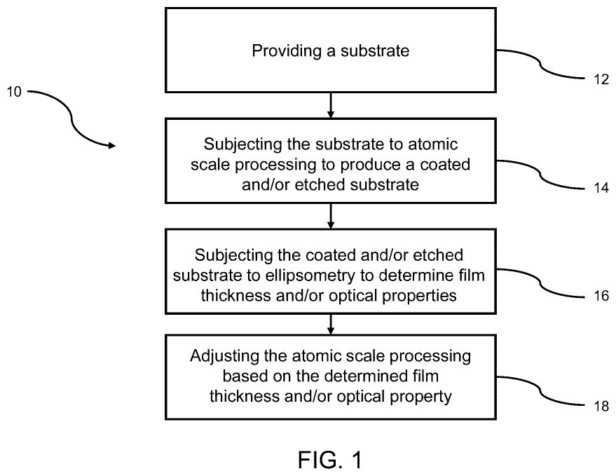

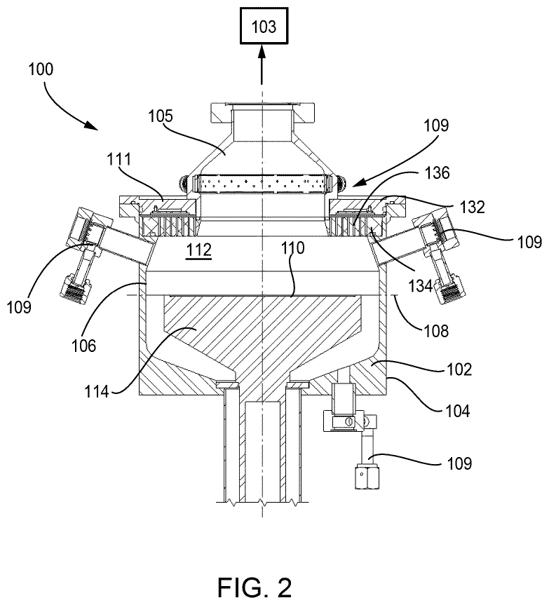

The present disclosure includes a method 10 of optimizing atomic scale processing of a coated and/or etched substrate. A non-limiting example of a method 10 of optimizing atomic scale processing of a coated and/or etched substrate is shown in FIG. 1. The method 10 of optimizing atomic scale processing of a coated and/or etched substrate can be performed by an atomic scale processing apparatus 100. Referring to FIG. 2, the optimizing atomic scale processing of a coated and/or etched substrate may be performed with an apparatus 100 for atomic scale processing. As such, the present disclosure also includes an apparatus for atomic scale processing that can optimize atomic scale processing of a coated and/or etched substrate.

For example, the atomic scale processing apparatus 100 may be an atomic layer deposition apparatus. As used herein, “atomic layer deposition” or “ALD” refers to a chemical vapor deposition (CVD) technique based on sequential, self-limiting surface reactions between gas/vapor phase species and active surface sites. ALD techniques include purely thermal and plasma-enhanced ALD (PEALD). The unique surface-controlled nature of ALD makes it an ideal choice for demanding applications requiring conformal, high-quality oxide and non-oxide based materials, as well as their interfaces. During ALD, at least two precursors may be pulsed (or dosed) sequentially into a reaction space where the substrate is located. A complete sequence (or cycle) may be made up of a series of pulse (or dose) and purge steps, such as at least 2 pulse and purge steps, or at least 3 pulse and purge steps, or at least 4 pulse and purge steps. A complete ALD cycle is therefore at least four steps, two dosage and two purge steps. Advantages of ALD methods include uniform, conformal surface coverage with atomic scale thickness and composition control. Sequential precursor pulsing (or dosing) eliminates the potential for gas-phase reactions that result in film defects so that highly reactive precursors can be utilized. Highly reactive precursors yield dense, continuous films with low levels of residual contamination and defects at relatively low process temperatures.

Similarly, the atomic scale processing apparatus 100 may be configured to perform atomic scale etching (ALE), including purely thermal and plasma-enhanced atomic layer etching (PEALE). ALE is similar to ALD in that it includes the same cycle of pulse (dose) and purge steps, such as at least 2 pulse and purge steps, or at least 3 pulse and purge steps, or at least 4 pulse and purge steps. However, during ALE, at least one of the precursors dosed to the substrate is configured interact and/or modify the surface of the substrate (or a coating/film on the surface of the substrate), thereby producing an etched substrate.

In some non-limiting embodiments, the atomic scale processing apparatus 100 may be an area selective atomic layer deposition apparatus. In this regard, the atomic scale processing apparatus 100 may be configured to perform one or more atomic scale processing techniques, such as atomic layer deposition (ALD), area selective atomic layer deposition (ASALD), atomic layer etching (ALE), plasma-enhanced atomic layer deposition (PEALD), plasma-enhanced atomic layer etching (PEALE), and/or the like. The atomic scale processing apparatus 100 may also be capable of surface engineering to modify surfaces (e.g., hydrocarbon and/or native oxide removal, surface oxidation and/or nitridation, hydroxyl formation, etc.) before and/or after deposition and/or removal of material from the substrate.

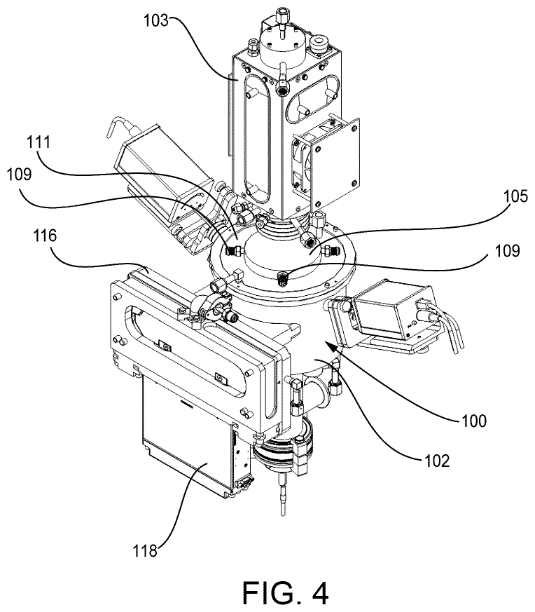

The method 10 may be performed in an atomic scale processing apparatus 100. The apparatus 100 may include a reactor 102. The reactor 102 may comprise outer surfaces 104 and inner surfaces 106. The inner surfaces 106 of the reactor 102 above the plane 108 of a substrate 110 defines an internal volume 112 of the reactor 102. A fixture assembly 114 may be within the internal volume 112. The fixture assembly 114 may have a surface configured to hold a substrate 110 within the internal volume 112 of the reactor 102. A transfer port 116 may be in communication with the reactor 102 and located at the front of the reactor 102, as shown in FIG. 4. A gate valve 118 may be in communication with the transfer port 116 and is configured to isolate the reactor 102.

The apparatus 100 geometry has a generally cylindrical symmetry, where the central axis is oriented vertically and perpendicular to the planar, circular surface of the fixture assembly 114. The central axis of the apparatus 100 passes through the origin of the fixture assembly 114 surface, and the fixture assembly 114 may include an embedded heating element for active heating of the substrate 110. The top surface of the fixture assembly 114 faces upward toward the top of the apparatus 100.

Multiple gas injection ports 109 are configured to facilitate the introduction of gas and/or vapor into the apparatus 100. As discussed hereinafter, the gas injection ports 109 may have the exclusive function of injecting gas into the apparatus 100, or may have multiple features associated therewith. For example, while some of the gas injection ports 109 may still serve to facilitate the introduction of gas into the apparatus 100, certain of the ports 109 may be used for viewing the internal volume 112 of the reactor 102, or otherwise directly or indirectly interacting with the internal volume 112 of the reactor 102. The gas injection ports 109 may extend through the outer surface 104 of the reactor 102 in order to introduce gases into the internal volume 112 of the reactor 102. The gas injection ports 109 may be configured to inject a gas, such as inactive gas, a precursor, and/or a co-reactant, into the internal volume 112 of the reactor 102.

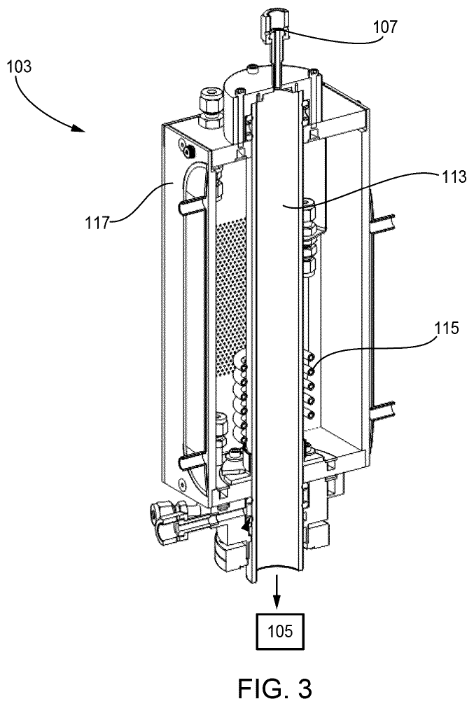

Atomic scale processing techniques include purely thermal and plasma enhanced ALD (PEALD) and ALE (PEALE). In some non-limiting embodiments, the apparatus 100 is configured to perform PEALD and PEALE, and the reactor 102 includes an inductively-coupled plasma (ICP) source 103, as shown in FIG. 3. The ICP source 103 may be coupled to a gas injection port 109, such as a plasma port 105. The ICP source 103 may be in communication with the reactor 102 and located above the reactor 102. The ICP source 103 may be configured to introduce (dose) plasma species into the internal volume 112 of the reactor 102 by enabling the ICP source 103. The ICP source 103 may include a cylindrical dielectric tube 113 where the axis of the tube is in-line with central axis of the apparatus 100. An ex situ electrode 115 may form a helix around the dielectric tube for plasma generation by applying power to the ex situ electrode 115, such as radiofrequency (RF) power; plasma generation is disabled by disabling power to the ex situ electrode 115. An enclosure 117 may be provided around the electrode 115 and dielectric tube 113 to shield RF radiation produced by the electrode 115, as well as radiation emitted by plasma species generated inside the dielectric tube 113. The apparatus 100 may include a plasma port 105 for connecting the ICP source 103 with the reactor 102. Gas from the process gas source 107 may be injected into the dielectric tube 113 of the ICP source 103, through the plasma port 105, and into the internal volume 112 of the reactor 102. However, if a plasma port 105 is not used, the lid assembly 111 can be optimized to include performance for thermal ALD and ALE processes.

A process gas source 107 may be in direct communication with the ICP source 103, thereby allowing process gas to flow into the dielectric tube 113 of the ICP source 103. A process gas can consist of an inactive gas such as Ar or N₂, and/or one or more precursor/plasma gases such as O₂, N₂, H₂, NH₃, Cl₂, SiH₄, F₂, H₂S, H₂Se, CF₄, CO, CO₂ and the like. As such, the present method 10 may include injecting a process gas into the ICP source 103.

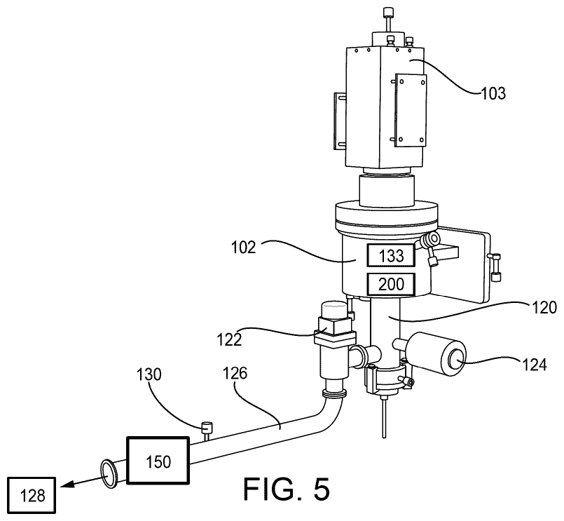

Referring to FIG. 5, an exhaust port 120 may be in communication with the reactor 102 and a pump isolation valve 122. A pressure gauge 124 may be attached to and in communication with the exhaust port 120 leading from the reactor 102. The pressure gauge 124 may be used to determine the pressure in the reactor 102 without introducing dead-space volume inside the reactor 102. A pump isolation valve 122 may be attached to a portion of the exhaust port 120 and a portion of the foreline 126. The pump isolation valve 122 may be opened or closed in order to isolate a pump 128 from the reactor 102. The foreline 126 may run from the reactor 102, to the pump isolation valve 122, and then to the pump 128. The pump 128 may be any suitable chemical series pump (may include mechanical pumps only, or a combination of mechanical and turbomolecular pumps) that enables the flow of process gases, over the required range of pressures and gas flow rates, through the reactor 102 and foreline 126 such that continuous, viscous-laminar flow is maintained. A downstream port 130 may be attached to and in communication with the foreline 126. The downstream port 130 provides purge and vent protection to reduce the potential for pump back-diffusion and back-streaming of impurities. For example, the downstream port 130 may be configured to provide continuous, viscous-laminar gas flow when the reactor 102 is not in communication with the pump 128. Therefore, pump 128 can remain on when the pump isolation valve 122 is closed without the risk of introducing impurities into the foreline 126 from the pump 128. The apparatus 100 may further include a throttle valve 150. The throttle valve 150 may be located on the foreline 126 and may be configured to modify the conductance between the reaction space volume within the internal volume 112 of the reactor 102 and the pump 128. The throttle valve 150 therefore can be used to control the effective pumping speed of the pump 128 to adjust residence time of species within the internal volume 112 of the reactor 102.

The apparatus 100 may further include a lid assembly 111, in which gas injection ports 109 extend through in order to introduce gases into the internal volume 112 of the reactor 102. The lid assembly 111 can be made from multiple, detachable components for flexibility, as well as to as to simplify manufacturing and serviceability.

The method 10 of optimizing atomic scale processing of a coated and/or etched substrate may include a step 12 of providing a substrate. The method 10 may include optimizing the atomic scale processing of any substrate capable of receiving precursor dosage and having a film formed or removed thereover. For example, the substrate 118 may comprise silicon (Si), germanium (Ge), sapphire (Al₂O₃), magnesium oxide (MgO), boron nitride (BN), aluminum nitride (AlN), gallium nitride (GaN), indium nitride (InN) and/or the like, with or without one or more overlayers. The substrate 118 may be positioned on a surface of a fixture assembly 114 that is positioned within the internal volume 112 of the reactor 102. This allows dosage of the surface of the substrate 118 and formation of a film and/or etching of a film on the substrate.

In some non-limiting embodiments, multiple precursor dosage steps (separated by purge steps) are implemented in the method 10 in order to form and/or remove a film on the substrate, thereby producing a coated and/or etched substrate. Multiple purge steps may be provided to purge precursor from the internal volume 112 of the reactor 102 after dosing steps. The method 10 may include providing a continuous flow of inactive gas into the internal volume 112 of the reactor 102. Inactive gas flow may be provided by at least one inactive gas dispersion arrangement 132 that is configured to introduce inactive gas into the internal volume 112 of the reactor 102. The at least one inactive gas dispersion arrangement 132 may be in fluid communication with one or more of the gas injection ports 109. The inactive gas dispersion arrangement 132 may include a primary dispersion member 134 having a thickness and multiple holes 136 extending therethrough. In this manner, at least a portion of the inactive gas introduced into the internal volume 112 of the reactor 102 occurs through one or more of the holes 136. Inactive gas flow provided by at least one inactive gas dispersion arrangement 132 has the benefit of creating a barrier which minimizes interactions between the precursor or co-reactant and the inner surfaces 106 of the reactor 102. Inactive gas flow may also be provided by one or more precursor vapor delivery arrangements 140a-b, an MFC arrangement as shown in FIG. 5C, and/or the process gas source 107.

The method 10 of optimizing atomic scale processing of a coated and/or etched substrate includes a step 14 of subjecting the substrate to atomic scale processing to produce a coated and/or etched substrate. For example, the ASP step 14 may include dosing a precursor to the surface of a substrate to produce a coated substrate and/or an etched substrate. The ASP step 14 may include dosing a precursor to the surface of a substrate to produce a coated and/or etched substrate, and purging the precursor from the internal volume of the reactor. In some non-limiting embodiments, more that one precursor dosage step may be implemented in the ASP step 14, such as at least two precursor dose steps separated by at least two purge steps. In some non-limiting embodiments, the ASP step 14 may include dosing a first precursor and/or dosing a second precursor to a surface of a substrate to produce a coated and/or etched substrate.

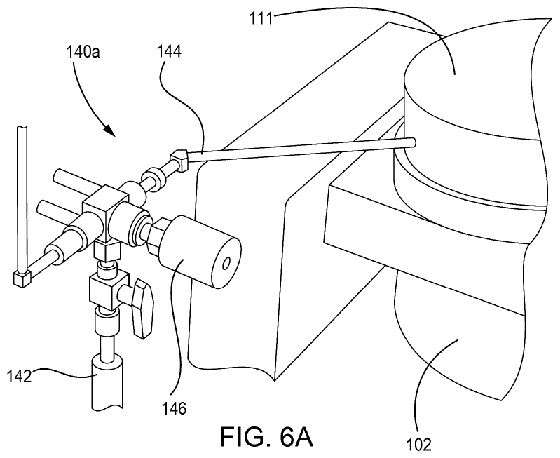

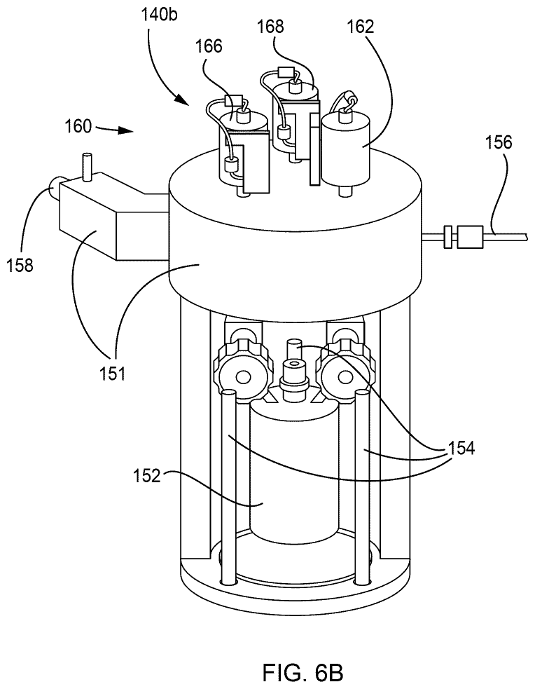

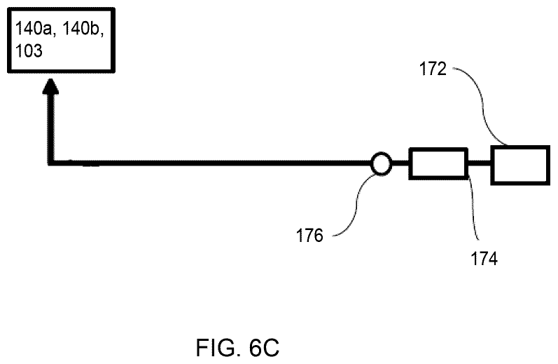

In some non-limiting embodiments, the ASP step 14 may include dosing the substrate with a first precursor and/or a second precursor to produce a coated and/or etched substrate. The dosing of the first precursor and/or the second precursor may be performed by at least one precursor delivery arrangement 140a-b, or by the ICP source 103, each of which may include an MFC arrangement. In this regard, a first precursor dosage source and a second precursor dosage source may be a precursor vapor delivery arrangement 140a-b, or can be an ICP source 103, each of which may include an MFC arrangement. FIG. 6A shows one example of a precursor vapor delivery arrangement 140a, however, any suitable precursor vapor delivery arrangement may be implemented. The at least one precursor vapor delivery arrangement 140a-b may be in communication with the reactor 102, such as in communication with one of the gas injection ports 109. The precursor vapor delivery arrangement 140a may include an ampoule 142 that includes a precursor. A line to the reactor 144 may be in communication with the ampoule 142 and the reactor 102, such as the ampoule 142 and one of the gas injection ports 109, such that the precursor may be transported to the reactor 102. A valve 146 may be attached to and in communication with the line to the reactor 144. The valve 146 may be opened or closed to control the introduction of precursor vapor from the ampoule 142 into the line to the reactor 144. The precursor vapor delivery arrangement 140a may include a mass flow controller which provides continuous, viscous-laminar inactive gas flow through valve 146 and the line to the reactor 144 for effective vapor delivery and subsequent purging of the delivery components. In some non-limiting embodiments, a valve 146 on a precursor vapor delivery arrangement 140a, such as a plurality of valves 146 on a plurality of precursor vapor delivery arrangements 140a, may be activated or deactivated to increase or decrease, respectively, the dosage of the first precursor and/or second precursor to the surface of the coated and/or etched substrate, such as to the surface of the coated and/or etched substrate positioned in the internal volume 112 of the reactor 102. As used herein, “activate” refers to a change in the configuration of the component (e.g., set point and/or the like) in order to cause an increase in the dosage of the first precursor and/or the second precursor to the surface of the coated and/or etched substrate, such as to the surface of the coated and/or etched substrate positioned in the internal volume 112 of the reactor 102. For example, a valve 146, such as a plurality of valves 146, may be activated by increasing the set point towards an open position. As used herein “deactivate” refers to a change in the configuration of the component (e.g., set point and/or the like) in order to cause a decrease in the dosage of the first precursor and/or the second precursor to the coated and/or etched substrate, such as to the coated and/or etched substrate positioned within the internal volume 112 of the reactor 102. For example, a valve 146, such as a plurality of valves 146, may be deactivated by decreasing the set point towards a closed position. The activation and/or deactivation of the valve 146, such as plurality of valves 146, may be commanded by the controller 200, as detailed herein.

In some non-limiting embodiments, the precursor vapor delivery arrangement 140a-b may be the precursor vapor delivery arrangement 140b of FIG. 6B and may include a lower oven enclosure to aid in temperature management. The precursor vapor delivery arrangement 140b may include a carrier gas input line 156 that is in communication with a carrier gas source to allow a carrier gas to flow into the precursor vapor delivery arrangement 140b. The precursor vapor delivery arrangement 140b may include a carrier gas output line 158 that is in communication with the reactor 102 to allow carrier gas to flow out of the precursor vapor delivery arrangement 140b and into the reactor 102. The precursor vapor delivery arrangement 140b may include an ampoule 152 that includes a liquid or solid phase precursor. The precursor vapor delivery arrangement 140b may include a valve manifold 160. The valve manifold 160 may include an input valve 162 that may be open or closed. When the input valve 162 is open, the input valve 162 allows the carrier gas from the carrier gas input line 156 to flow into the ampoule 152. When the input valve 162 is closed, the input valve 162 prevents the carrier gas from entering the ampoule 152. The valve manifold 160 may include an output valve 166 that may be open or closed. When the output valve 166 is open, the output valve 166 allows the carrier gas present in the ampoule 152 to flow out of the ampoule 152 and into the carrier gas output line 158. When the output valve 166 is closed, the output valve 166 prevents the carrier gas from exiting the ampoule 152. The valve manifold 160 may include a bypass valve 168 that may be open or closed. When the bypass valve 168 is open, the bypass valve 168 allows the carrier gas to flow from the carrier gas input line 156 to the carrier gas output line 158 without entering the ampoule 152.

When dosing of a precursor to the reactor 102 is not needed, the input valve 162 and the output valve 166 may be closed and the bypass valve 168 may be open such that the carrier gas cannot flow to the ampoule 152 to pick up the precursor vapor in the ampoule 152, but instead, the carrier gas flows from the carrier gas input line 156 to the bypass valve 168 and then to the carrier gas output line 158. The carrier gas flow rate may be from approximately 10 to 100 standard cubic centimeters per minute (sccm). When precursor dosing is needed, the bypass valve 168 is closed and the input valve 162 and the output valve 166 are opened simultaneously or with a programmed delay. This configuration allows the carrier gas to flow from the carrier gas input line 156, into the ampoule 152 where the carrier gas picks up the precursor vapor therein, and then the carrier gas with the precursor vapor flow into the carrier gas output line 158 which transports the carrier gas and the precursor vapor to the reactor 102. Alternatively, during precursor dosing, the bypass valve 168 may be closed and only the input valve 162 may be opened, simultaneously or with a programmed delay, leaving the output valve 166 closed. This configuration allows carrier gas to flow from the carrier gas input line 156 to the ampoule 152 without letting the carrier gas exit the ampoule 152 to the carrier gas output line 158. This valve configuration allows for pressure in the ampoule 152 head-space to increase, such as an increase to 10-20 Torr inside the ampoule 152, compared to the approximate pressure inside the reactor 102 of 1 Torr. Once a sufficient pressure increase in the ampoule 152 is achieved, the output valve 166 may be opened, thereby allowing the carrier gas with precursor vapor to flow into the carrier gas output line 158 and then to the reactor 102. The increased pressure inside the ampoule 152 head-space from the output valve 166 being closed allows for the carrier gas and precursor vapor to be more uniformly distributed inside the reactor 102 and across the substrate 110. When dosing is completed, the bypass valve 168 may be opened and the input valve 162 and the output valve 166 may be closed, simultaneously or with a programmed delay, thus allowing the carrier gas to flow from the carrier gas input line 156, to the bypass valve 168, and then to the carrier gas output line 158, thereby avoiding the ampoule 152 to prevent dosing and enable purging for the delivery channel. The precursor vapor delivery arrangement 140b may include one or more independently controlled heat zones to aid in temperature management. For example, the precursor vapor delivery arrangement 140b may include a first independently controlled heat zone at the ampoule 152. The precursor vapor delivery arrangement 140b may include a second independently controlled heat zone at the valve manifold 160. The precursor vapor delivery arrangement 140b may include a third independently controlled heat zone around the carrier gas output line 158. The precursor vapor delivery arrangement 140b may also include a mass flow controller (MFC), such as the MFC arrangement in FIG. 6C, located upstream from the valve manifold 160, which provides continuous, viscous-laminar inactive gas flow through the valve manifold 160 and the carrier gas output line 158 for effective vapor delivery and subsequent purging of the delivery components.

In some non-limiting embodiments, the input valve 162 and the output valve 166 on a precursor vapor delivery arrangement 140b, such as a plurality of input valves 162 and output valves 166 on a plurality of precursor vapor delivery arrangements 140b, may be activated or deactivated to increase or decrease, respectively, the dosage of the first precursor and/or second precursor to the surface of the coated and/or etched substrate, such as to the surface of the coated and/or etched substrate positioned in the internal volume 112 of the reactor 102. For example, the input valve 162 and the output valve 166 may be activated by increasing the set point towards an open position. In another example, the input valve 162 and the output valve 166 may be deactivated by decreasing the set point towards a closed position. The activation and/or deactivation of the input valve 162 and the output valve 166 may be commanded by the controller 200, as detailed herein.

The lower oven enclosure may include a heater jacket 151, or some other suitable means of supplying thermal energy, around at least a portion of an ampoule 152. In some non-limiting embodiments, the heater jacket 151, or some other suitable means of supplying thermal energy, may be provided around the entire circumference of the ampoule 152. The lower oven enclosure may include at least two heater cartridges 154, such as two heater cartridges 154, spaced squally apart from each other, between the ampoule 152 and the heater jacket 151. For example, the lower oven enclosure may include at least three heater cartridges 154, such as three heater cartridges 154, spaced equally apart from each other between the ampoule 152 and the heater jacket 151.

As shown in FIG. 6C, a mass flow controller (MFC) arrangement may be provided. The MFC arrangement may be provided that may be implemented upstream from any precursor vapor or gas delivery arrangements, such as the precursor vapor delivery arrangement 140a-b disclosed herein, or the ICP source 103 disclosed herein. For example, the MFC arrangement of FIG. 6C may be implemented upstream from the ICP source 103 of FIG. 3, the precursor vapor delivery arrangement 140a of FIG. 6A, and/or the precursor vapor delivery arrangement 140b of FIG. 6B. More than one MFC arrangement may be present if multiple process gases are desired. For example, at least one MFC arrangement, or at least two MFC arrangements, or at least three MFC arrangements, each containing the same or different inactive process gases, may be implemented upstream from the precursor vapor delivery arrangement 140a-b or the ICP source 103. An MFC arrangement includes a gas source 172. For example, the gas source 172 may be an inactive gas source and may contain Ar or N₂. In another example, the gas source 172 may be a reactant gas source and may contain NH₃, N₂H₄, H₂, O₂, HF, HCl and the like. In another example, the gas source 172 may be a reactant plasma gas source and may contain O₂, N₂, H₂, NH₃, Cl₂, SiH₄, F₂, H₂S, H₂Se, CF₄, CO, CO₂ and the like, and may provide reactant gas flow through the ICP source 103. An MFC 174 may be in communication with the gas source 172. The MFC 174 may be used to control the continuous flow of gas through the precursor vapor delivery arrangement 140a-b or ICP source 103. Continuous, viscous-laminar inactive gas flow serves as a carrier gas during precursor delivery/dose steps, and as a purge gas during subsequent purge steps. This inactive gas flow also creates a diffusion barrier to prevent unwanted back-diffusion of downstream impurities into the vapor delivery channel. The MFC arrangement further includes a valve 176 that may be open or closed to allow or prevent gas flow to the precursor vapor delivery arrangement 140a-b or to the ICP source 103. The valve 176 is in communication with both the MFC 174 and the precursor vapor delivery arrangement 140a-b or ICP source 103.

In some non-limiting embodiments, the valve 176 on the MFC arrangement may be activated or deactivated to increase or decrease, respectively, the dosage of the first precursor and/or second precursor to the surface of the coated and/or etched substrate, such as to the surface of the coated and/or etched substrate positioned in the internal volume 112 of the reactor 102. For example, the valve 176 may be activated by increasing the set point towards an open position. In another example, the valve 176 may be deactivated by decreasing the set point towards a closed position. The activation and/or deactivation of the valve 176 may be commanded by the controller 200, as detailed herein. In combination with activation and/or deactivation of the valve 176, the gas flow rate from a corresponding MFC 174 may be increased and/or decreased by controller 200 to further modify precursor dosage of the first and/or second precursor to the surface of a coated and/or etched substrate.

In some non-limiting embodiments, the dosing steps of the ASP step 14 may be performed by at least one precursor vapor delivery arrangement 140a-b, or at least two precursor vapor delivery arrangements 140a-b, or at least three precursor vapor delivery arrangements 140a-b, at least four precursor vapor delivery arrangements 140a-b. In some non-limiting embodiments, a first precursor vapor delivery arrangement 140a-b is provided for dosing the first precursor, and a second precursor vapor delivery arrangement 140a-b is provided for dosing the second precursor. In some non-limiting embodiments, one of the precursor vapor delivery arrangements may be a ICP source 103 and one of the precursors may be plasma.

In some non-limiting embodiments, the ASP step 14 may include dosing the surface of the substrate with a first precursor for at least 0.01 s, or at least 1 s, or at least 2 s, or at least 3 s, or at least 4 s, or at least 5 s, or at least 6 s, or at least 10 s, or at least 15 s, or at least 20 s, or at least 25 s. The ASP step 14 may include dosing the surface of the substrate with a first precursor for up to 25 s, or up to 20 s, or up to 15 s, or up to 10 s. The time of dosage of the first precursor is determined based on how long the valve 146 of the precursor vapor delivery arrangement 140a or the valve manifold 160 of the precursor vapor delivery arrangement 140b (i.e., the input valve 162 and the output valve 166), or similar valve/means on the ICP source 103 (such as on the process gas source 107), is open, and/or the valve 176 on the MFC arrangement is open, if present. In combination with the opening of valve 176 on the MFC arrangement, the gas flow rate from a corresponding MFC 174 may be set to enable gas flow through the ICP source 103.

In some non-limiting embodiments, the first precursor may comprise a metal halide and/or a metal organic compound. Non-limiting examples of metal halide precursors include the following: titanium tetrachloride (TiCl₄), tin tetrachloride (SnCl₄), tantalum pentachloride (TaCl₅), niobium pentachloride (NbCl₅), molybdenum pentachloride (MoCl₅), aluminum trichloride (AlCl₃), boron trichloride (BCl₃), aluminum tribromide (AlBr₃), tungsten hexafluoride (WF₆), and the like. Non-limiting examples of metal organic precursors include trimethylaluminum (TMA), trimethylindium (TMIn), trimethylgallium (TMGa), tetrakis(dimethylamino) hafnium (TDMAH), tetrakis(dimethylamino) zirconium (TDMAZ), tetrakis(dimethylamino) titanium (TDMAT), tetrakis(dimethylamino) tin (TDMASn), tris(i-propylcyclopentadienyl) lanthanum (La(iPrCp)₃), pentakis(dimethylamino) tantalum (PDMAT), tantalum ethoxide (Ta(OEt)₅), niobium ethoxide (Nb(OEt)₅), tert-butylimido)tris(diethylamino) niobium (TBTDEN), bis(ethylcyclopentadienyl) scandium chloride (ClSc(EtCp)₂), trimethyl(methylcyclopentadienyl) platinum (Me₃PtCpMe), bis(ethylcyclopentadienyl) ruthenium (Ru(EtCp)₂), bis(ethylcyclopentadienyl) nickel (Ni(EtCp)₂), tris(dimethylamino) borane (TDMAB), and the like. Non-limiting examples of other precursors include: oxygen (O₂), ozone (O₃), hydrogen peroxide (H₂O₂), nitrogen (N₂), ammonia (NH₃), hydrazine (N₂H₄), hydrogen (H₂), silane (SiH₄), chlorine (Cl₂), fluorine (F₂), hydrogen sulfide (H₂S), hydrogen selenide (H₂Se), Hydrogen fluoride (HF), hydrogen fluoride-pyridine (HF-pyridine), hydrogen chloride (HCl), carbon tetrafluoride (CF₄), carbon dioxide (CO₂), carbon monoxide (CO) and the like.

In some non-limiting embodiments, the ASP step 14 may include purging the first precursor from the internal volume 112 of the reactor 102. The purging of the first precursor may include purging the first precursor from the internal volume 112 of the reactor 102 by injecting, such as continuously injecting, inactive gas into the internal volume 112 of the reactor 102, such as by injecting through the available gas injection ports 109 and 132. Non-limiting examples of inactive gases include Ar, N₂, and the like. The inactive gas injected through gas injection ports 109 and 132 flows through reactor 102, to exhaust port 120, to foreline 126 and to pump 128, which efficiently removes all remaining first precursor and/or reaction byproducts. In this regard, the first precursor is prevented from entering the reactor 102 after dosage, so that inactive gas can flow through the reactor 102 and remove excess first precursor and/or reaction byproducts. In some non-limiting embodiments, the ASP step 14 may include purging the first precursor from the internal volume 112 of the reactor 102 for at least 0.1 s, or at least 1 s, or at least 5 s, or at least 10 s, or at least 15 s, or at least 20 s, or at least 25 s, or at least 30 s. The ASP step 14 may include purging the first precursor from the internal volume 112 of the reactor 102 for up to 40 s, or up to 35 s, or up to 30 s, or up to 25 s, or up to 20 s. The time of purging the first precursor from the internal volume 112 of the reactor 102 is determined based on how long the valve 146 on the precursor vapor delivery arrangement 140a, the valve manifold 160 of the precursor vapor delivery arrangement 140b (i.e., the input valve 162 and the output valve 166), or similar valve/means on the ICP source 103 (such as on the process gas source 107), and/or the valve 176 of the MFC arrangement is closed after being open for dosage and before the second precursor is dosed, such as by opening a valve to dose the second precursor and/or generating plasma species using ICP source 103 by enabling power to the ex situ electrode 115.

In some non-limiting embodiments, the ASP step 14 may further include dosing the surface of the substrate 118 with a second precursor. The dosing of the surface of the substrate 118 with a second precursor may be performed by at least one precursor vapor delivery arrangement 140a-b or an ICP source 103, each of which can include an MFC arrangement as shown in FIG. 6C. For example, the apparatus 100 may include at least two precursor vapor delivery arrangements 140a-b, where one arrangement is for dosing the first precursor and the second arrangement is for dosing the second precursor, where one of the arrangement may be an ICP source 103 for dosing plasma. The precursor vapor delivery arrangement 140a-b and/or ICP source 103 may include an MFC arrangement as shown in FIG. 6C. In some non-limiting embodiments, the second precursor may comprise a metal halide and/or a metal organic compound. Non-limiting examples of metal halide precursors include the following: titanium tetrachloride (TiCl₄), tin tetrachloride (SnCl₄), tantalum pentachloride (TaCl₅), niobium pentachloride (NbCl₅), molybdenum pentachloride (MoCl₅), aluminum trichloride (AlCl₃), boron trichloride (BCl₃), aluminum tribromide (AlBr₃), tungsten hexafluoride (WF₆), and the like. Non-limiting examples of metal organic precursors include trimethylaluminum (TMA), trimethylindium (TMIn), trimethylgallium (TMGa), tetrakis(dimethylamino) hafnium (TDMAH), tetrakis(dimethylamino) zirconium (TDMAZ), tetrakis(dimethylamino) titanium (TDMAT), tetrakis(dimethylamino) tin (TDMASn), tris(i-propylcyclopentadienyl) lanthanum (La(iPrCp)₃), pentakis(dimethylamino) tantalum (PDMAT), tantalum ethoxide (Ta(OEt)₅), niobium ethoxide (Nb(OEt)₅), tert-butylimido)tris(diethylamino) niobium (TBTDEN), bis(ethylcyclopentadienyl) scandium chloride (ClSc(EtCp)₂), trimethyl(methylcyclopentadienyl) platinum (Me₃PtCpMe), bis(ethylcyclopentadienyl) ruthenium (Ru(EtCp)₂), bis(ethylcyclopentadienyl) nickel (Ni(EtCp)₂), tris(dimethylamino) borane (TDMAB), and the like. Non-limiting examples of other precursors include: oxygen (O₂), ozone (O₃), hydrogen peroxide (H₂O₂), nitrogen (N₂), ammonia (NH₃), hydrazine (N₂H₄), hydrogen (H₂), silane (SiH₄), chlorine (Cl₂), fluorine (F₂), hydrogen sulfide (H₂S), hydrogen selenide (H₂Se), Hydrogen fluoride (HF), hydrogen fluoride-pyridine (HF-pyridine), hydrogen chloride (HCl), carbon tetrafluoride (CF₄), carbon dioxide (CO₂), carbon monoxide (CO) and the like. In some non-limiting embodiments, the atomic scale processing may be thermal ALD or ALE. For example, the atomic scale processing may be thermal ALD and the second precursor may be ammonia (NH₃), hydrazine (N₂H₂), or a mixture thereof. Alternatively, the second precursor may be plasma. In some non-limiting embodiments, the atomic scale processing may be plasma-enhanced ALD (PEALD) or plasma-enhanced ALE (PEALE). For example, the atomic scale processing may be PEALD and the second precursor may be plasma. In such an embodiment, the apparatus 100 may include at least one precursor vapor delivery arrangement 140a-b for dosing the first precursor and an ICP source 103 for dosing plasma, each of which may include an MFC arrangement as shown in FIG. 6C. The plasma species may include N₂, H₂, NH₃, N₂H₄, Ar and the like, and mixtures thereof (e.g., N₂—H₂, N₂—H₂—Ar, NH₃, NH₃—Ar, NH₃—H₃—N₂—H₂, NH₃—N₂—H₂—Ar, etc.).

In some non-limiting embodiments, the ASP step 14 may include dosing the surface of the substrate 118 with a second precursor for at least 0.01 s, or at least 1 s, or at least 5 s, or at least 10 s, or at least 15 s, or at least 20 s, or at least 25 s. The ASP step 14 may include dosing the surface of the substrate 118 with a second precursor for up to 40 s, or up to 35 s, or up to 30 s, or up to 25 s, or up to 20 s, or up to 15 s, or up to 10 s. The time of dosage of the second precursor is determined based on how long the valve 146 of the precursor vapor delivery arrangement 140a or the valve manifold 160 of the precursor vapor delivery arrangement 140b (i.e., the input valve 162 and the output valve 166), or similar valve/means on the ICP source 103 (such as on the process gas source 107), is open, and/or the valve 176 on the MFC arrangement is open, if present. In some non-limiting embodiments, the method 10 may be at room temperature (approximately 23° C.), or may include heating the surface of the substrate 118 in the internal volume 112 of the reactor 102. The surface of the substrate may be heated to a temperature of at least 50° C., or at least 100° C., or at least 125° C., or at least 150° C., or at least 175° C., or at least 200° C. The surface of the substrate 118 may be heated to a temperature of up to 400° C., or up to 350° C., or up to 300° C., or up to 250° C., or up to 225° C., or up to 215° C. The surface of the substrate may be heated to a temperature in the range of from 100° C. to 400° C., or in the range of from 125° C. to 350° C., or in the range of from 150° C. to 300° C., or in the range of from 175° C. to 250° C., or in the range of from 200° C. to 225° C., or in the range of from 200° C. to 215° C.

In some non-limiting embodiments, the ASP step 14 may include purging the second precursor from the internal volume 112 of the reactor 102. The ASP step 14 may include purging the second precursor from the internal volume 112 of the reactor 102 by injecting, such as continuously injecting, inactive gas into the internal volume 112 of the reactor 102, such as by injecting through the available gas injection ports 109 and 132. Non-limiting examples of inactive gases include Ar, N₂, and the like. The inactive gas flow through the gas injection ports 109 and 132 flows through reactor 102, to exhaust port 120, to foreline 126 and to pump 128, which efficiently removes all remaining second precursor and/or reaction byproducts. In this regard, the second precursor is prevented from entering the reactor 102 after dosage, so that inactive gas can flow through the reactor 102 and remove excess second precursor and/or reaction byproducts. In some non-limiting embodiments, the ASP step 14 may include purging the second precursor from the internal volume 112 of the reactor 102 for at least 0.1 s, or for at least 1 s, or at least 2 s, or at least 3 s, or at least 4 s, or at least 5 s, or at least 10 s, or at least 15 s, or at least 20 s. The dosing step 14 of the method 10 may include purging the second precursor from the internal volume 112 of the reactor 102 for up to 30 s, or up to 25 s, or up to 20 s, or up to 15 s, or up to 10 s, or up to 5 s. The time of purging the second precursor from the internal volume 112 of the reactor 102 is determined based on how long the valve 146 on the precursor vapor delivery arrangement 140a, the valve manifold 160 of the precursor vapor delivery arrangement 140b (i.e., the input valve 162 and the output valve 166), or similar valve/means on the ICP source 103 (such as on the process gas source 107), and/or the valve 176 of the MFC arrangement is closed after being open for dosage, and optionally before dosing a subsequent precursor, if desired, such as before opening a valve to allow dosage of a subsequent precursor and/or generating plasma species using ICP source 103 by enabling power to the ex situ electrode 115. This process of a first precursor dosage, first precursor purge, second precursor dosage, and second precursor purge may be referred to as a single process cycle of an ASP process. In some non-limiting embodiments, the ASP step 14 may include at least one process cycle, or at least two process cycles, or at least three process cycles, or at least four process cycles, or at least five process cycles.

In some non-limiting embodiments, the method 10 of optimizing atomic scale processing of a coated and/or etched substrate may include forming and/or removing the film under ultra-high purity (UHP) conditions. As used herein, “ultra-high purity conditions” refer to an impurity partial pressure inside the internal volume 112 of the reactor 102 being less than 10⁻⁶ Torr. Common impurities include O₂, H₂O, carbon monoxide (CO), carbon dioxide (CO₂). UHP conditions may be established according to the methods and apparatuses disclosed in U.S. Pat. No. 11,621,571, the disclosure of which is hereby incorporated by reference in its entirety. UHP conditions may limit the role of background impurities during atomic scale processing, thereby preventing unwanted reaction pathways that can adversely affect the quality of deposited and/or etched layers.

UHP conditions are based on reduced levels of background impurities to limit their role in surface reactions before, during, and after film growth and/or etch by atomic scale processing techniques, such as limiting the incorporation of background oxygen impurities in nitride thin films. UHP conditions are also important in surface engineering where extremely tight control over the surface composition is paramount. For example, preparation of III-V elements, as well as other non-silicon based, semiconductor channel materials (including 2D materials) for subsequent high-k gate integration. Establishing UHP conditions are also important for ALD/PEALD of elemental metals such as Ti, Al, Ta, and the like, where, similar to nitrides, lowering oxygen content is extremely important. Since most transition and p-block metals tend to readily oxidize, this present some significant equipment design challenges that require careful consideration in order to reduce exposure to background impurities, such as oxygen species before, during, and after film growth.

To establish a UHP process environment inside the reactor 102, the partial pressure of background impurities must be reduced to less than 10⁻⁶ Torr (i.e., less than one Langmuir, or monolayer equivalent, exposure every second). Since water vapor is a very common and problematic background impurity for the growth of non-oxide based materials, it is used here to establish the upper limit (i.e., 10⁻⁶ Torr partial pressure) for defining UHP process conditions. To establish this requirement, it is instructive to first consider the specifications for a UHP grade (99.999% purity) process gas such as Ar and N₂. UHP grade Ar/N₂ contains oxygen impurities up to the ppm level. As discussed previously, these impurities include O₂, H₂O, CO and CO₂. For Ar/N₂ at 1 Torr pressure, the ppm level corresponds to 10⁻⁶ Torr partial pressure. For an impurity such as H₂O at 10⁻⁶ Torr partial pressure, a growing nitride surface experiences 1 Langmuir H₂O exposure every second (1 Langmuir=106 Torr s). Under these conditions, if each H₂O molecule striking the surface adsorbs (or sticks), then ~1 monolayer surface coverage every second would be subsequently obtained. A typical PEALD process deposits less than a monolayer of material per each complete cycle (one complete cycle=one full sequence of precursor dose and purge steps). Typical PEALD cycle times range from approximately 10-60 seconds. Therefore, each sub-monolayer of material deposited experiences 10-60 Langmuir exposures (or 10-60 monolayer equivalent exposures) from water vapor at the 10⁻⁶ Torr level every second.

In some non-limiting embodiments, the method 10 of optimizing the atomic scale processing of a coated and/or etched substrate may include a step 16 of subjecting the coated and/or etched substrate to ellipsometry. For example, the step 16 may include subjecting the coated and/or etched substrate to in situ ellipsometry. The method for ASP optimization described herein includes the evaluation of film properties, such as film thickness and optical properties, in real-time, during deposition and/or etch, by in situ ellipsometry, which is shown in FIG. 7. Ellipsometry may be performed by an ellipsometer 133 that forms part of the atomic scale processing apparatus 100. In this regard, properties (e.g., film thickness, optical properties, and/or the like) of the coated and/or etched substrate can be obtained during film formation and/or etching without removing the coated and/or etched substrate from the internal volume 112 of the reactor 102. The step 16 of subjecting the coated and/or etched substrate to ellipsometry may be performed during a process cycle, or alternatively, may be performed in between process cycles. The step 16 of subjecting the coated and/or etched substrate to ellipsometry may be performed during dosing of the first precursor and/or the second precursor to the surface of the coated and/or etched substrate positioned in the internal volume 112 of the reactor 102. The step 16 of subjecting the coated and/or etched substrate to ellipsometry may be performed during purging of the first precursor and/or the second precursor within the internal volume 112 of the reactor 102.

The ellipsometer 133 may be any ellipsometer known in the art that is capable of emitting a beam of light and measuring the change in polarization of the beam of light after reflecting off of a surface. The ellipsometer 133 includes a light source 135. The light source 135 may be configured to direct a beam of light 137 at a sample, such as the coated and/or etched substrate positioned in the internal volume 112 of the reactor 102. In this regard, the step 16 of subjecting the coated and/or etched substrate to ellipsometry may include directing a beam of light 137 with a wavelength at the surface of the coated and/or etched substrate, such as directing a beam of light 137 with a wavelength at the surface of the coated and/or etched substrate positioned in the internal volume 112 of the reactor 102. In some non-limiting embodiments, the step 16 of subjecting the coated and/or etched substrate to ellipsometry may include directing a beam of light 137 with a plurality of wavelengths at the surface of the coated and/or etched substrate, such as directing a beam of light 137 with a plurality of wavelengths at the surface of the coated and/or etched substrate positioned in the internal volume 112 of the reactor 102. In such an embodiment, the ellipsometer 133 may be a multiwavelength ellipsometer, capable of producing a beam of light 137 with a plurality of discrete wavelengths, or a more continuous spectrum of wavelengths commonly referred to as a spectroscopic ellipsometer. The light source 135 may be configured to direct a beam of light 137 of known wavelength at the sample. For example, the light source 135 may be configured to direct a beam of light 137 having a plurality of known discrete wavelengths (or range of wavelengths) at a sample, such as the coated and/or etched substrate positioned in the internal volume 112 of the reactor 102. The beam of light 137 may have a wavelength, such as a plurality of discrete wavelengths (or range of wavelengths), with a value within the electromagnetic spectrum. For example, the beam of light 137 can include ultraviolet (UV) light, visible light, infrared (IR) light, or a combination thereof. For example, the beam of light 137 may have a wavelength, such as a plurality of discrete wavelengths (or range of wavelengths), in the range of from 1 nm to 1,000,000 nm, or in the range of from 100 nm to 100,000 nm, or in the range of from 100 nm to 10,000 nm, or in the range of from 100 nm to 1,000 nm, or in the range of from 200 nm to 1,000 nm, or in the range of from 300 nm to 1,000 nm, or in the range of from 300 nm to 900 nm, or in the range of from 300 to 800 nm.

In some non-limiting embodiments, the ellipsometer 133 includes a polarizer 139. The polarizer 139 may be positioned between the light source 135 and the sample, such as the light source 135 and the coated and/or etched substrate positioned within the internal volume 112 of the reactor 102. The polarizer 139 may be configured to polarize the beam of light 137 from the light source 135 as it passes through the polarizer 139. In this regard, the beam of light 137 that reaches the sample, such as the coated and/or etched substrate, is understood as polarized light 141. As such, the step 16 of subjecting the coated and/or etched substrate to ellipsometry may include polarizing the beam of light 137 to produce polarized light 141. The polarized light 141 may contact the surface of the coated and/or etched substrate at an angle of incidence θᵢ. The polarized light 141 may reflect off of the surface of the coated and/or etched substrate at an angle of reflection θᵣ. The angle of incidence θᵢ is the same as the angle of reflection θᵣ, such that specular reflection is achieved.

The ellipsometer 133 may further include an analyzer 143. The analyzer 143 may include another polarizer the same or similar to the polarizer 139 positioned between the sample and the light source 135. However, the analyzer 143 is configured to quantify the change in the polarization state of the beam of light 141 after the beam of light 141 has interacted and reflected off of the surface of the sample; the corresponding intensity is measured by the detector 145. In this regard, the analyzer 143 is positioned such that the beam of light 141 passes through the analyzer 143 after specularly reflecting off of the surface of the sample, such as off of the coated and/or etched substrate positioned in the internal volume 112 of the reactor 102. The step 16 of subjecting the coated and/or etched substrate to ellipsometry may include measuring a change in the polarization state of the polarized light 141 after the polarized light 141 interacts and reflects off of the surface of the coated and/or etched substrate, such as off the surface of the coated and/or etched substrate positioned in the internal volume 112 of the reactor 102.

The change in the polarization state of the polarized light 141, measured by ellipsometry, produces elliptical sample polarization data that may be used to determine various properties of the coated and/or etched substrate and the film, or films, positioned on the substrate. For example, the measured change in the polarization state of the polarized light 141 produces elliptical sample polarization data that may be used to determine film thickness and/or optical properties (e.g., refractive index, extinction coefficient, optical bandgap, optical resistivity, and/or optical conductivity) associated with the coated and/or etched substrate, such as the coated and/or etched substrate positioned in the internal volume 112 of the reactor 102. The step 16 of subjecting the coated and/or etched substrate to ellipsometry may include determining a film thickness and/or an optical property of the coated and/or etched substrate by comparing the sample polarization data to a model. The step 16 of subjecting the coated and/or etched substrate to ellipsometry may include determining an optical property including refractive index, extinction coefficient, optical bandgap, optical resistivity, and/or optical conductivity of the coated and/or etched substrate positioned in the internal volume 112 of the reactor 102. It is typical in ellipsometry applications to compare and/or fit the experimental data from the ellipsometer to a model that has been constructed based on the predicted behavior of the film materials (e.g., first precursor and/or second precursor), also referred to as an ellipsometric model, to determine parameters such as film thickness and/or optical properties. For example, the model may be a three-layer ellipsometric model comprising a silicon substrate, a native oxide layer over the silicon substrate, and a Cauchy layer over the native oxide layer. The ellipsometric model may have additional layers, less layers, or different layers comprising different materials, some depending on the first precursor and/or second precursor. The ellipsometric model may also utilize a substrate other than silicon, such as germanium, sapphire, boron nitride, aluminum nitride, gallium nitride, indium nitride and the like, which may include additional layers, less layers or different layers comprising different materials, some depending on the first precursor and/or second precursor. In some non-limiting embodiments, the ellipsometer 133 may obtain various parameters associated with the reflected polarized light 141 that are used to evaluate film thickness and/or optical properties. The ellipsometer 133 may obtain the amplitude ratio (tan Ψ) and a phase difference (Δ) associated with the reflected polarized light 141. These values may then be used to determine the complex reflectance ratio (ρ) using the following formula:

ρ=tan(Ψ)*e^{iΔ}

However, the experimentally determined amplitude ratio and phase difference usually cannot be used to directly determine properties associated with the coated and/or etched substrate. Instead, a model is established which considers the expected optical parameters and thickness parameters of the layers of the coated article. These parameters can then be varied to establish a model that fits the experimental ellipsometric data.

In some non-limiting embodiments, the ellipsometer 133 may further include a detector 145. The detector 145 may be a component that is capable of quantifying one or more parameters of the light that is received by the detector. For example, the detector 145 may receive the reflected polarized light 141 that passes through the analyzer 143, and is capable of quantifying the intensity of the received light, which is utilized in determining the film thickness and/or optical properties of the coated and/or etched substrate.

It is noted that the ellipsometer 133 described herein is a non-limiting example of an ellipsometer 133 that may be implemented in the methods and/or apparatuses described herein. In some non-limiting embodiments, the ellipsometer 133 may include additional components, less components, or different components of an ellipsometer 133 that are known in the art.

In some non-limiting embodiments, the method 10 of optimizing the atomic scale processing of a coated and/or etched substrate may include a step 18 of adjusting the atomic scale processing based on the determined film thickness and/or refractive index. In some non-limiting embodiments, the adjusting step 18 may include adjusting the dosage of a precursor based on the determined film thickness and/or optical property. For example, the adjusting step 18 may include adjusting the dosage of a first precursor and/or a second precursor based on the determined film thickness and/or optical property. In some non-limiting embodiments, the adjusting step 18 may include increasing the dosage of the first precursor and/or second precursor based on the determined film thickness and/or the determined optical property. In some non-limiting embodiments, the adjusting step 18 may include decreasing the dosage of the first precursor and/or second precursor based on the determined film thickness and/or optical property. In some non-limiting embodiments, the adjusting step 18 may include adjusting the dosing of the first precursor and/or second precursor with a controller 200 based on the evaluated film thickness and/or optical property. In this regard, the atomic scale processing apparatus 100 may include a controller 200 that is configured to control the adjusting of the dosage of the first precursor and the second precursor. Alternatively, the adjusting step 18 may include adjusting the dosing of the first precursor and/or second precursor by another means, such as manually (e.g., by hand). A controller 200 may also carry out a programed series of dosage adjustments, where the determined film thickness and/or optical properties are subsequently determined by controller 200 to evaluate the first precursor and/or the second precursor dose saturation behavior.

In some non-limiting embodiments, the adjusting step 18 may include adjusting the purging of a precursor from the internal volume 112 of the reactor 102 based on the determined film thickness and/or optical property. For example, the adjusting step 18 may include adjusting the purging of a first precursor and/or a second precursor from the internal volume 112 of the reactor 102 based on the determined film thickness and/or optical property. In some non-limiting embodiments, the adjusting step 18 may include increasing the purge time of the first precursor and/or second precursor from the internal volume 112 of the reactor 102 based on the determined film thickness and/or the determined optical property. In some non-limiting embodiments, the adjusting step 18 may include decreasing the purge time of the first precursor and/or second precursor based on the determined film thickness and/or optical property. In some non-limiting embodiments, the adjusting step 18 may include adjusting the purging of the first precursor and/or second precursor with a controller 200 based on the evaluated film thickness and/or optical property. In this regard, the atomic scale processing apparatus 100 may include a controller 200 that is configured to control the adjusting of the purging of the first precursor and the second precursor. Alternatively, the adjusting step 18 may include adjusting the purging of the first precursor and/or second precursor by another means, such as manually (e.g., by hand). A controller 200 may also carry out a programed series of purging adjustments, where the determined film thickness and/or optical properties are subsequently determined by controller 200 to evaluate the first precursor and/or the second precursor purge saturation behavior.

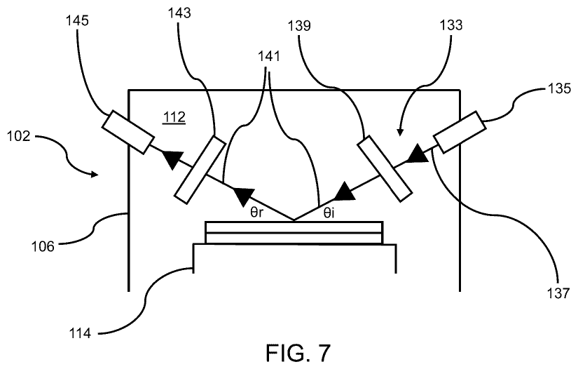

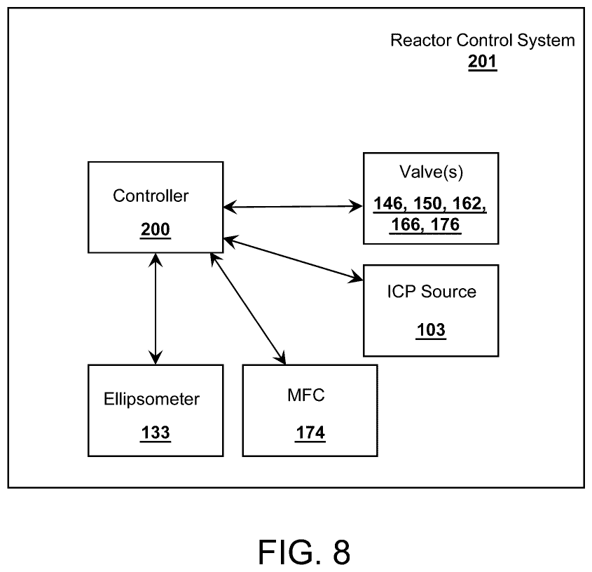

Referring to FIG. 8, a diagram of a reactor control system 201 is provided. As shown in FIG. 8, the reactor control system 201 may include at least a controller 200, an ellipsometer 133, an ICP source 102, and MFC 174, and at least one valve, such as valve 146, throttle valve 150, input valve 162 and output valve 166, and/or valve 176. The controller 200, the ellipsometer 133, the ICP source 103, the MFC 174, and at least one valve may interconnect (e.g., establish a connection to communicate and/or the like) via wired connections, wireless connections, or a combination thereof.

The controller 200 may include a device that is capable of being in communication with the controller 200, the ellipsometer 133, and at least one valve. Any suitable valve may be implemented in the reactor control system 201, such as the valve 146, an input valve 162 and output valve 166 of a valve manifold 160, the throttle valve 150, and/or a valve 176 of an MFC arrangement. In addition to valves, there are other system components that may require communication with the controller 200 for ASP optimization, such as enabling and disabling the plasma source 103 by enabling and disabling power to the ex situ electrode 115, as well as adjusting one or more MFC 174 gas flow rates. The components listed herein are non-limiting examples of components that may be controlled by the controller 200, such that other components of the apparatus 100 may be interconnected and commanded by the controller 200. The controller 200 may receive data associated with one or more components of the reactor control system 201. For example, the controller 200 may receive data associated with the ellipsometer 133, such as the current film thickness and/or optical properties. The controller 200 may provide commands (e.g., instructions, signals, and/or the like) to at least one component of the reactor control system 201. For example, the controller 200 may provide commands to the at least one valve 146, or an input valve 162 and output valve 166 of a valve manifold 160, or the plasma source 103, or the throttle valve 150, or adjusting one or more MFC 174 gas flow rates. The controller 200 may provide commands based on the received data associated with one or more components of the reactor control system 201, such as from the ellipsometer 133.

The ellipsometer 133 may be capable of being in communication with the controller 200. The ellipsometer 133 may be configured to determine the film thickness and/or optical properties of the coated and/or etched substrate based on polarization data, and send the determined film thickness and/or optical properties to the controller 200. The controller 200 may provide commands to at least one valve 146, or an input valve 162 and output valve 166 of a valve manifold 160, or the throttle valve 150, or the valve 176, or the plasma source 103, or adjusting one or more MFC 174 gas flow rates, based on the data received from the ellipsometer 133.

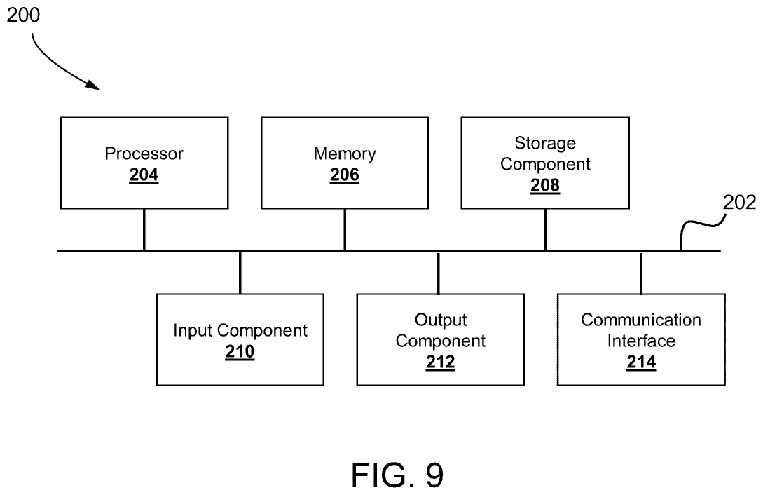

Referring to FIG. 9, a diagram of example components of a controller 200 are provided. As shown in FIG. 9, the controller 200 may include a bus 202, a processor 204, memory 206, a storage component 208, an input component 210, an output component 212, and a communication interface 214. The controller 200 may be implemented and form a component of the atomic scale processing apparatus 100 described herein.

The bus 202 may include a component that permits communication among the components of the controller 200. The processor 204 may be implemented in hardware, software, or a combination thereof. For example, the processor 204 may include a processor (e.g., a central processing unit (CPU), a graphic processing unit (GPU), an accelerated processing unit (APU), and/or the like), a microprocessor, a digital signal processor (DSP), and/or similar processing components that can be programmed to perform a function. Memory 206 may include random access memory (RAM), read-only memory (ROM), and/or another type of dynamic or static storage device (e.g., flash memory, magnetic memory, optical memory, and/or the like) that stores information, data, and/or instructions for use by the processor 204.

The storage component 208 may store information and/or software related to the operation and use of the controller 200. For example, storage component 208 may include a hard disk (e.g., magnetic disk, an optical disk, a magneto-optic disk, a solid state disk, and/or the like), a compact disc (CD), a digital versatile disc (DVD), a floppy disk, a cartridge, a magnetic tape, and/or another type of computer-readable medium, along with a corresponding drive.

The input component 210 may include a component that permits the controller 200 to receive information, such as via user input (e.g., a touchscreen display, a keyboard, a keypad, a mouse, a button, a switch, a microphone, a camera, and/or the like). The output component 212 may include a component that provides output information from the controller 200 (e.g., a display, a speaker, one or more light emitting diodes (LEDs), and/or the like).

The communication interface 214 may include a transceiver-like component (e.g., a transceiver, a separate receiver and transmitter, and/or the like) that enables the controller 200 to communicate with other devices and/or components, such as via a wired connection, a wireless connection, or a combination thereof. The communication interface 214 may permit the controller 200 to receive information from another device and/or a component and/or provide information to another device and/or a component. For example, the communication interface 214 may include an Ethernet interface, an optical interface, a coaxial interface, an infrared interface, a radio frequency (RF) interface, a universal serial bus (USB) interface, a Wi-Fi® interface, a Bluetooth® interface, a Zigbee® interface, a cellular network interface, and/or the like.

The controller 200 may perform one or more processes described herein. The controller 200 may perform these processes based on processor 204 executing software instructions stored by a computer-readable medium, such as memory 206 and/or the storage component 208. A computer-readable medium (e.g., non-transitory computer-readable medium) is defined herein as a non-transitory memory device. A non-transitory memory device includes memory space spread across multiple physical storage devices.

Software instructions can be read into memory 206 and/or the storage component 208 from another computer-readable medium or from another device and/or component via the communication interface 214. When executed, the software instructions stored in memory 206 and/or the storage component 208 may cause the processor 204 to perform one or more processes described herein. Additionally or alternatively, hardwired circuitry may be used in place of or in combination with software instructions to perform one or more processes described herein. Thus, embodiments described herein are not limited to any specific combination of hardware circuitry and software.

The number and arrangement of components shown in FIG. 9 are provided as an example. In some non-limiting embodiments, the controller 200 may include additional components, fewer components, different components, or differently arranged components than those shown in FIG. 9. Additionally, or alternatively, a set of components of the controller 200 may perform one or more functions described as being performed by another set of components of the controller 200.

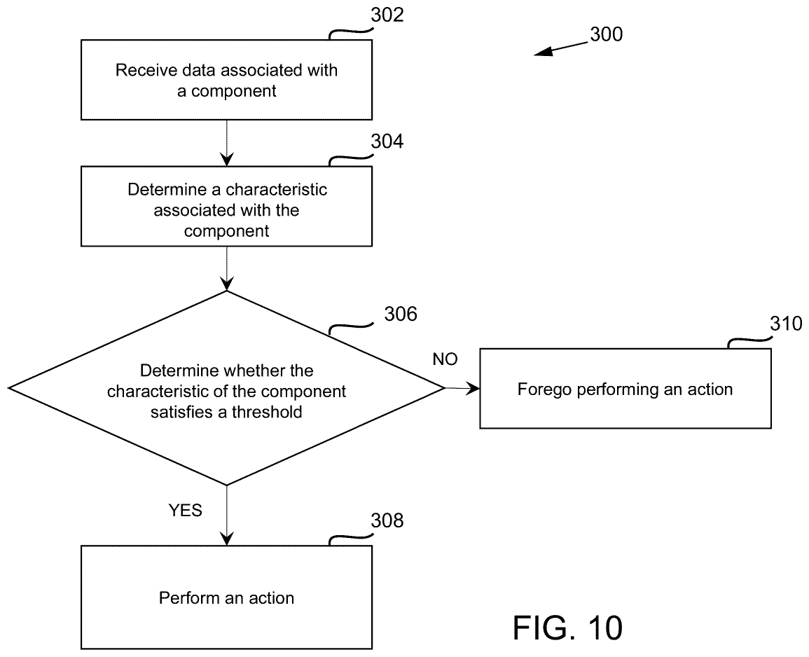

Referring to FIG. 10, a flowchart of a non-limiting embodiment of a process 300 that may be performed (e.g., completely, partially, etc.) by the controller 200. In some non-limiting embodiments, one or more of the steps of process 300 may be performed by another device and/or component separate from and/or including the controller 200.

As shown in FIG. 10, the process 300 may include a step 302 of receiving data associated with a component. For example, the controller 200 may receive data associated with the ellipsometer 133 from the ellipsometer 133. In some non-limiting embodiments, the data associated with the ellipsometer 133 may be information (e.g., a characteristic, a parameter, etc.) that is determined (e.g., measured, detected, sensed, obtained, calculated, etc.) by the ellipsometer 133 in the course of operation of the ellipsometer 133.

As shown in FIG. 10, the process 300 can include a step 304 of determining a characteristic associated with the component. For example, the controller 200 may determine a characteristic associated with the ellipsometer 133. The controller 200 may determine film thickness information and/or optical property information associated with the ellipsometer 133. The thickness information associated with the ellipsometer 133 may include the film thickness of the film of the coated and/or etched substrate that is determined by the ellipsometer 133 using the ellipsometry data obtained by the ellipsometer 133. Optical property information may include the refractive index, the optical bandgap, optical resistivity, optical conductivity, and/or the extinction coefficient of the film of the coated and/or etched substrate that is determined by the ellipsometer 133 using the ellipsometry data obtained by the ellipsometer 133. In some non-limiting embodiments, the step 304 of determining a characteristic associated with the component may include determining a plurality of characteristics associated with a component, such as the ellipsometer 133. For example, the controller 200 may determine a plurality of film thicknesses and/or plurality of optical properties associated with the ellipsometer 133. In this regard, the controller 200 may be programmed to run a plurality of atomic scale processing cycles (at least one dose step and at least one purge step), and vary one of the process parameters to determine the optimal process conditions. The process parameter that may be varied includes the first precursor dosage time, first precursor purge time, second precursor dosage time, second precursor purge time, and substrate temperature. The ellipsometer 133 may then determine a plurality of film thicknesses and/or optical properties based on varying the one process parameter. The controller 200 may obtain this plurality of film thickness and/or optical property values from the ellipsometer 133 to determine the optimal process conditions. In some non-limiting embodiments, the controller 200 may obtain and/or determine a plurality of film thickness and/or optical property values for a given process parameter set point, and subsequently produce a curve of the growth behavior of the film at the process parameter set point to determine the saturation behavior at that process parameter set point. In this regard, the controller 200 may carry out a programed series of process parameter adjustments, with the ellipsometer 133 taking a plurality of measurements to determine film thickness and/or optical property values for each process parameter adjustment so that the saturation behavior of the growth can be analyzed and optimized.

As shown in FIG. 10, the process 300 may include a step 306 of determining whether the characteristic of the component satisfies a threshold. For example, the controller 200 may determine whether the characteristic associated with the ellipsometer 133 (e.g., film thickness, optical properties, and/or the like) satisfies a threshold. The threshold may include a threshold value based on a film thickness value, or series of film thickness values. For example, the threshold may include a film thickness value, that when below said film thickness value, indicates that the film thickness growth is less than desired and/or expected. In another example, the threshold may include a film thickness value, that when above said film thickness value, indicates that the film growth is greater than desired and/or expected. If the film thickness satisfies the threshold, the film thickness is the desired thickness and/or has the desired growth behavior. In another example, the threshold may include a series of film thickness values that may show a constant value, or saturation behavior, consistent with a self-limiting growth and/or etch of a material on the surface of a substrate. In such an example, satisfying the threshold will be the varied process parameter value that most closely matches the saturation behavior of the film thickness values that form the threshold. This saturation behavior threshold may include a plurality of film thicknesses over the growth of a film which shows the saturation behavior of the growth. The threshold may include an optical property value (e.g., refractive index, extinction coefficient, optical resistivity, and/or conductivity). For example, the threshold may include an optical property value (e.g., refractive index, extinction coefficient, optical resistivity, and/or conductivity), that when below said optical property value (e.g., refractive index, extinction coefficient, optical resistivity, and/or conductivity), indicates that the film growth is inconsistent with what is desired and/or expected. In another example, the threshold may include an optical property value (e.g., refractive index, extinction coefficient, optical resistivity, and/or conductivity), that when above said optical property value (e.g., refractive index, extinction coefficient, optical resistivity, and/or conductivity), indicates that the film growth is inconsistent with what is desired and/or expected. When the optical property value is equal to the threshold, the film growth is what is desired and/or optimized. In another example, the threshold may include a series of optical property values that show a constant value, or saturation behavior. In such an example, satisfying the threshold will be the varied process parameter value that most closely matches the saturation behavior of the optical property values that form the threshold. This saturation behavior threshold may include a plurality of optical property values over the growth of a film which shows the saturation behavior of optical property.

As shown in FIG. 10, the process 300 may include a step 308 (“YES”) of performing an action based on determining that the characteristic associated with the component satisfies a threshold. For example, the controller 200 may perform an action based on determining that the characteristic associated with the ellipsometer 133 satisfies the threshold. The controller 200 may perform an action based on determining that the film thickness associated with the ellipsometer 133 satisfies the threshold. For example, the controller 200 may perform an action based on determining that the film thickness value associated with the ellipsometer 133 satisfies the threshold, indicating that the film thickness of the film of the coated article corresponds to what is desired (optimized). The controller 200 may perform the action by adjusting the atomic scale processing to a process parameter value that is associated with the film thickness that satisfies the threshold. The process parameter may be the first precursor dosage time, first precursor purge time, second precursor dosage time, second precursor purge time, or substrate temperature. For example, the controller 200 may receive a film thickness that is associated with a particular process parameter value, and because said film thickness satisfies the threshold, the controller 200 will adjust the atomic scale processing to include the particular process parameter value that is associated with the film thickness that satisfies the threshold. In another example, the controller 200 may carry out a programed series of adjustments of a process parameter, such that the controller 200 may receive a plurality of film thicknesses from the ellipsometer 133 for each process parameter value (e.g., first precursor dosage time, first precursor purge time, second precursor dosage time, second precursor purge time, or substrate temperature). In such an example, the plurality of film thicknesses may demonstrate a saturation behavior of the film growth. The controller 200 may perform an action based on determining which process parameter value produces a saturation behavior that satisfies the threshold (i.e., saturation behavior), such as by adjusting the atomic scale processing to the process parameter value associated with the process parameter value that produces a saturation behavior that satisfied the threshold. For example, if the controller 200 varied the dosage time of a first precursor, and the controller 200 determines that the saturation behavior associated with a dosage time of 6 seconds satisfies the threshold, then the controller 200 may adjust the atomic scale processing such that the dosage time of the first precursor is 6 seconds. The controller 200 may perform an action based on determining that an optical property value (e.g., refractive index, extinction coefficient, optical resistivity, and/or conductivity) associated with the ellipsometer 133 satisfies a threshold. For example, the controller 200 may perform an action based on determining that the optical property value (e.g., refractive index, extinction coefficient, optical resistivity, and/or conductivity) associated with the ellipsometer 133 satisfies the threshold, indicating that the film growth is desired and/or expected. The controller 200 may perform the action by adjusting the atomic scale processing to a process parameter value that is associated with the optical property value that satisfies the threshold. The process parameter may be the first precursor dosage time, first precursor purge time, second precursor dosage time, second precursor purge time, or substrate temperature. For example, the controller 200 may receive an optical property that is associated with a particular process parameter value, and because said optical property satisfies the threshold, the controller 200 will adjust the atomic scale processing to include the particular process parameter value that is associated with the optical property that satisfies the threshold. In another example, the controller 200 may carry out a programed series of adjustments of a process parameter, such that the controller 200 may receive a plurality of optical property values from the ellipsometer 133 for each process parameter value (e.g., first precursor dosage time, first precursor purge time, second precursor dosage time, second precursor purge time, or substrate temperature). In such an example, the plurality of optical property values for each process parameter value may demonstrate a saturation behavior of the film growth and/or etch. The controller 200 may perform an action based on determining which process parameter value produces optical property values that produce a saturation behavior that satisfies the threshold (i.e., saturation behavior), such as by adjusting the atomic scale processing to the process parameter value associated with the process parameter value that produces a saturation behavior that satisfied the threshold. For example, if the controller 200 varied the dosage time of a first precursor, and the controller 200 determines that the saturation behavior produced by the optical property values associated with a dosage time of 6 seconds satisfies the threshold, then the controller 200 may adjust the atomic scale processing such that the dosage time of the first precursor is 6 seconds. In some non-limiting embodiments, the controller 200 may require user input in order to confirm that the controller 200 is to perform the action.

As shown in FIG. 10, the process 300 can include a step 310 (“NO”) of foregoing performing an action based on determining that the characteristic associated with the component does not satisfy the threshold. For example, the controller 200 may forego performing an action based on determining that the characteristic associated with the ellipsometer 133 does not satisfy the threshold. The controller 200 may compare the film thickness value associated with the ellipsometer 133 to the threshold, and, if the controller 200 determines that the film thickness value associated with the ellipsometer 133 does not satisfy the threshold, the controller 200 may forego performing the action. For example, the controller 200 may compare the film thickness value associated with the ellipsometer 133 to the threshold, and, if the controller 200 determines that the film thickness value associated with the ellipsometer 133 is above or below the threshold, the controller 200 may forego performing the action. In another example, the controller 200 may carry out a programed series of adjustments of a process parameter, such that the controller 200 may receive a plurality of film thicknesses from the ellipsometer 133 for each process parameter value (e.g., first precursor dosage time, first precursor purge time, second precursor dosage time, second precursor purge time, or substrate temperature). In such an example, the plurality of film thicknesses may demonstrate a saturation behavior of the film growth. The controller 200 may forego performing an action based on determining which process parameter values produce a saturation behavior from the film thickness values that does not satisfy the threshold (i.e., saturation behavior), such as by not adjusting the atomic scale processing to the process parameter values associated with the process parameter values that do not satisfy the threshold. For example, if the controller 200 varied the dosage time of a first precursor, and the controller 200 determines that the saturation behaviors associated with a dosage times of 1, 10, and 20 seconds does not satisfy the threshold, then the controller 200 may forego adjusting the atomic scale processing such that the dosage time of the first precursor is not 1, 10, or 20 seconds. In some non-limiting embodiments, the controller 200 may compare an optical property value (e.g., refractive index, extinction coefficient, optical resistivity, and/or conductivity) associated with the ellipsometer 133 to the threshold, and, if the controller 200 determines that the optical property value (e.g., refractive index, extinction coefficient, optical resistivity, and/or conductivity) does not satisfy the threshold, the controller 200 may forego performing the action. For example, the controller 200 may compare the optical property value (e.g., refractive index, extinction coefficient, optical resistivity, and/or conductivity) associated with the ellipsometer 133 to the threshold, and, if the controller 200 determines that the optical property value (e.g., refractive index, extinction coefficient, optical resistivity, and/or conductivity) is above or below the threshold, the controller 200 may forego performing the action. In another example, the controller 200 may carry out a programed series of adjustments of a process parameter, such that the controller 200 may receive a plurality of optical property values from the ellipsometer 133 for each process parameter value (e.g., first precursor dosage time, first precursor purge time, second precursor dosage time, second precursor purge time, or substrate temperature). In such an example, the plurality of optical property values may demonstrate a saturation behavior of the film growth. The controller 200 may forego performing an action based on determining which process parameter values produce a saturation behavior from the optical property values that does not satisfy the threshold (i.e., saturation behavior), such as by not adjusting the atomic scale processing to the process parameter values associated with the process parameter values that do not satisfy the threshold.

The following Examples are presented to demonstrate the general principles of the invention of this disclosure. The invention should not be considered as limited to the specific examples presented.

### Examples

### Experimental Background

### Film Deposition

The films described in these Examples were formed using PEALD under ultra-high purity conditions (UHP-C). The depositions were performed in an ALD150LX perpendicular-flow reactor from the Kurt J. Lesker Company (Jefferson Hills, PA). The scandium precursor used was bis(ethylcyclopentadienyl)scandium-chloride (ClSc(EtCp)₂), available from Dockweiler Chemicals GmbH (Marburg, Germany). This heteroleptic compound is a solid at room temperature, with a melting point at 95° C. ClSc(EtCp)₂ was contained in a stainless steel flow-ampoule and kept at 180° C. to develop adequate vapor pressure for delivery. The vapor pressure was approximately 0.2 Torr. The process gases used were Ar, N₂ (99.999%, Airgas), and H₂ (99.999%, Linde). Scandium nitride films were grown by PEALD at a substrate temperature from 200-300° C. using ClSc(EtCp)₂ and a mixture of N₂ and H₂ (N₂—H₂) plasma species as reactants.

The dose of ClSc(EtCp)₂ is defined as the amount of time the associated ALD valves on the “in” and “out” sides of the flow-through ampoule were held open, using a precursor vapor delivery arrangement such as that shown in FIG. 6B. During ClSc(EtCp)₂ dose and exposure steps, a downstream butterfly valve, i.e., the throttle valve 150 of FIG. 5, was used to limit conductance between the reactor and pump, thereby increasing the pressure and Sc precursor residence time inside the reactor. N₂—H₂ plasma was generated at ~0.3 Torr by a remote inductively coupled plasma (ICP) source operating at 13.56 MHz frequency and 600 W plasma power. The plasma gas flow rates were 40 sccm N₂ and 5 sccm H₂ (8:1), which was established by an MFC arrangement as shown in FIG. 6C. The reactor pressure was maintained at ~1 Torr during ClSc(EtCp)₂ and N₂—H₂ plasma purge steps. ScN films were grown on silicon (Si), sapphire (Al₂O₃) and magnesium oxide (MgO) substrates; more specifically, untreated 150 mm Si (100), 50 mm Al₂O₃ (0001) and 1 cm×1 cm MgO (001) substrates.

### Testing Background

### Ellipsometry and X-Ray Reflectivity (XRR)

Scandium nitride film thickness and optical properties were determined ex situ by spectroscopic ellipsometry (SE) using a M-2000 spectroscopic ellipsometer, available from J.A. Woollam (Lincoln, Nebraska), over a range of wavelengths from 193-1000 nm. Ellipsometry measurements were also performed in situ during scandium nitride film growth using a FS-8 multiwavelength ellipsometer, available from Film Sense (Lincoln, Nebraska), providing eight wavelengths of ellipsometric data (367 nm, 449 nm, 526 nm, 594 nm, 656 nm, 735 nm, 852 nm, and 949 nm). In both cases, a Cauchy model was used to determine the scandium nitride film thickness and the refractive index. To avoid the effects of direct band gap absorption when modeling the ellipsometric data, the fitted data were limited to wavelengths of greater than or equal to 526 nm.

A X'Pert³ MRD x-ray diffractometer, available from Malvern Panalytical (Malvern, United Kingdom), was used to obtain x-ray reflectivity (XRR) measurements in order to confirm the film thickness measured by ellipsometry.

### X-Ray Photoelectron Spectroscopy (XPS)

The film composition was measured by depth profile x-ray photoelectron spectroscopy (XPS) using a VersaProbe III instrument, available from Physical Electronics (Chanhassen, Minnesota) equipped with a monochromatic Al kα x-ray source (1486.6 eV) and a concentric hemispherical analyzer. Quantification utilized instrumental relative sensitivity factors (RSFs) that account for the x-ray cross section and inelastic mean free path of the electrons. For the major elements (Sc, N), the 1σ quantitative accuracy is expected to be within ±10 rel %. Due to poor counting statistics, and finite background levels of C and O, the 1σ accuracy is expected to be within ±20-40 rel % for the minor elements. Ion sputtering was accomplished using a 2 kV Ar⁺ ion beam. Since detection of low levels of C and O were of interest, films were evacuated to <2×10⁻⁹ Torr prior to starting measurements. C and O were acquired first in the depth profile to minimize any re-adsorption of C- and O-containing gases from the residual gases in the XPS chamber. This resulted in a lower limit of detection for both elements of ~0.1-0.2 at. %.

### X-Ray Diffraction (XRD)

The structural phase of as deposited ScN was investigated by grazing incidence x-ray diffraction (GIXRD) using an Empyrean diffractometer, available from Malvern Panalytical (Malvern, United Kingdom). Out-of-plane XRD and phi-scans were performed using Rigaku (Tokyo, Japan) Smartlab and Malvern Panalytical (Malvern, United Kingdom) Empyrean diffractometers, respectively.

### Field Emission Scanning Electron Microscopy (FESEM)

To evaluate 3-D conformality, silicon trenches with a 1:4 aspect ratio were fabricated by deep reactive ion etching (RIE) and subsequently coated with silicon nitride. The sample was then sectioned by edge cleaving and focused ion beam milling with a Scios 2 DualBeam, available from Thermo Scientific (Waltham, MA), and finally imaged using a Gemini 500 field emission scanning electron microscope, available from Zeiss (Oberkochen, Germany). Silicon nitride deposited on planar Si was also imaged to investigate film morphology.

### Hall Probe

ScN electrical properties were investigated using 4-probe, 300×300 μm Hall bar patterns fabricated on both ScN/Al₂O₃ and ScN/MgO. Contact pads were fabricated of 20 nm Pd followed by 50 nm Au. The Hall resistance was measured using a current of 1 mA and with the magnetic field swept from negative-to-positive 2900 Gauss, with the data demonstrating highly linear behavior. For each sample, five devices were measured with average results provided in Table 3.

### Deposition Results

### Film Development

Scandium nitride films were measured in real-time during growth by in situ multiwavelength ellipsometry (MWE) to assist in the development of the scandium nitride PEALD process. The thickness and index of the evolving scandium nitride film were determined using an ellipsometric model consisting of a silicon substrate, native oxide layer, and Cauchy-ScN layer. ScN growth-per-cycle (GPC) vs. ClSc(EtCp)₂ precursor dose time was investigated on untreated 150 mm Si (100) substrates to determine the dose saturation behavior of the PEALD process at substrate temperatures ranging from 200-300° C.

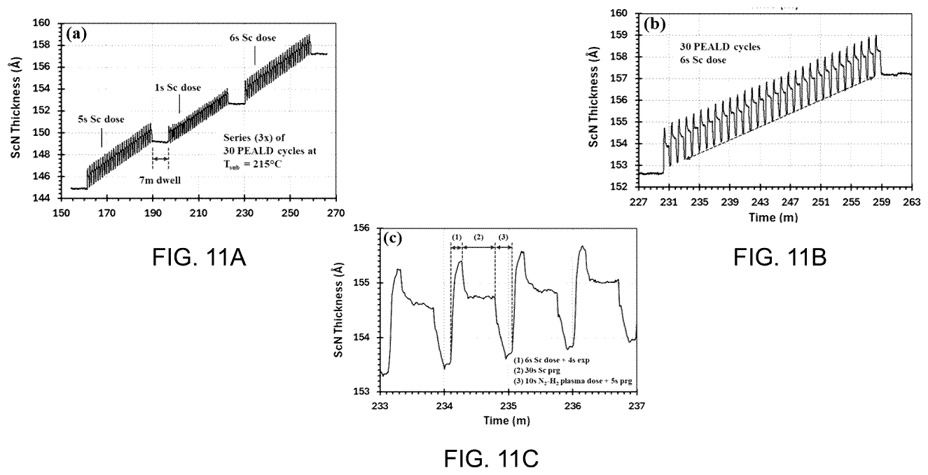

The method used to generate this data is as follows. For each of the investigated substrate temperatures, a design-of-experiments (DOE) was carried out on a single-pristine 150 mm Si (100) substrate, whereby 30 PEALD cycles were performed for each of the evaluated ClSc(EtCp)₂ precursor dose times. For example, FIG. 11A shows a series of 30 PEALD cycles corresponding to 5, 1 and 6 s ClSc(EtCp)₂ precursor dose times at 215° C. substrate temperature. Note that a ScN base-layer (~10 nm thick) was first deposited by PEALD on a bare Si (100) substrate in situ to mitigate any subsequent nucleation delay associated with the silicon native oxide surface. The order of the 30-cycle depositions in FIG. 11A is randomized with respect to dose time to further ensure that no artifacts related to the experimental method affected the reported GPC values. To normalize process conditions as well as provide a separation in the data for subsequent analysis, each 30-cycle deposition is separated by a 7-minute dwell time under inert gas flow and repeated 3× for reproducibility. The dose times investigated ranged from 0.5-7 s, where ScN GPC values were determined from the slope of the corresponding growth profiles as illustrated in FIG. 11B.

For this investigation, the Sc precursor exposure and purge times remained fixed at 4 and 30 s; and the N₂—H₂ plasma dose and purge times were fixed at 10 and 5 s, respectively. The MWE data were subsequently analyzed using the following three-layer ellipsometric model: (1) Si substrate (at growth temperature), (2) native oxide layer and (3) Cauchy-ScN layer. The native oxide thickness was determined prior to the ScN base-layer growth. This model was used to determine the total ScN thickness and the refractive index at dwell times between each 30-cycle deposition. The corresponding index ranged between 2.14 and 2.62 at 200° C. and 300° C., respectively. Index values were then used to fit each preceding 30 cycle growth profile and extract the GPC based on slope. The slope indicated in FIG. 11B corresponds to the ScN growth rate. GPC is obtained by multiplying the growth rate by the ScN PEALD cycle time. Finally, FIG. 11C identifies the general features of the PEALD ScN step profile determined by MWE for a 6 s Sc precursor dose.

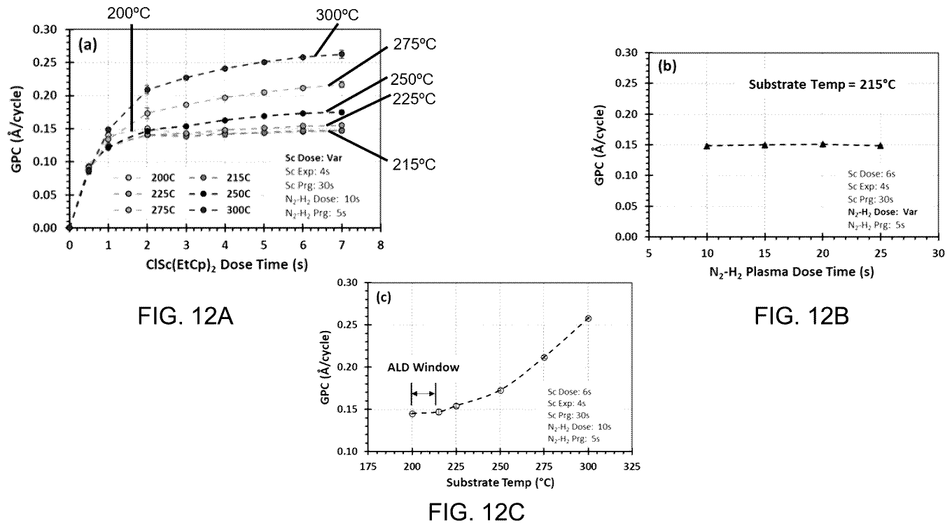

ClSc(EtCp)₂ dose saturation curves are presented in FIG. 12A, where each datapoint represents the average of three identical ScN depositions (error bars included). As observed in FIG. 12A, the GPC saturates at ~0.15 Å/cycle with increasing ClSc(EtCp)₂ dose time at 200° C. and 215° C. Similar saturation behavior is seen at 225° C. with increasing ClSc(EtCp)₂ dose time, but the GPC is slightly higher. This behavior is also observed in FIG. 12C, where the GPC at 215° C. also shows a very slight increase compared to the GPC measured at 200° C. At substrate temperatures above 225° C., non-saturation becomes more evident with increasing dose time, along with more significant changes in the overall GPC with increasing substrate temperature as demonstrated in FIGS. 12A and 12C. As identified in FIG. 12C, these results indicate that an ALD window exists between 200-215° C. substrate temperature. At temperatures ≥225° C., the continued increase in GPC with ClSc(EtCp)₂ dose time and/or substrate temperature are indicative of pyrolysis of the Sc precursor.

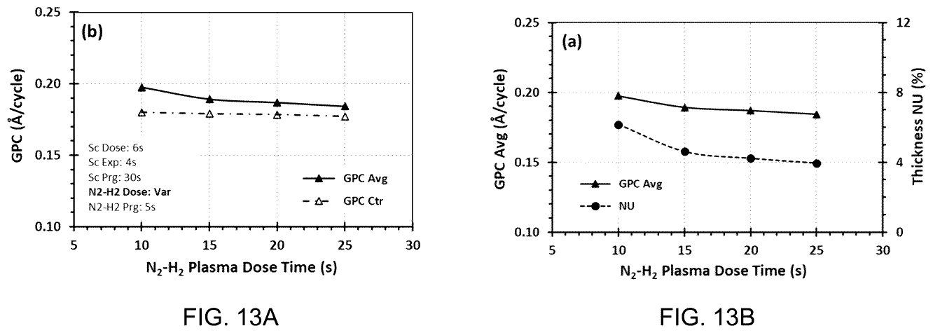

The N₂—H₂ plasma dose saturation curve presented in FIG. 12B shows no variation in the GPC between 10 and 25 s dose time, indicating that a 10 s plasma dose is sufficient to achieve saturation in the center of the reactor. SE measurements performed ex situ, however, revealed that ScN thickness uniformity across 150 mm Si substrates was improved by increasing the N₂—H₂ plasma dose time (see FIG. 13A-B).

Specifically, SE measurements were carried out ex situ to investigate N₂—H₂ plasma dose saturation across untreated 150 mm Si (100) substrates. GPC averages shown in FIG. 13A-B correspond to the thickness averages divided by the number of PEALD cycles. Compared to average values, the ScN GPC determined at the center of the substrate remained constant with N₂—H₂ plasma dose time as shown in FIG. 13A. The data shown in FIG. 13B demonstrates that film thickness NU is reduced by increasing the N₂—H₂ plasma dose time. Due to accelerated growth observed during the initial nucleation & growth phase of ScN PEALD on native Si oxide, the GPC determined ex situ is higher in FIGS. 13A-B compared to values reported for in situ measurements (e.g., see FIG. 12B).

Based on these results, the following process parameters were used to grow thicker PEALD ScN at 215° C. for subsequent characterization: ClSc(EtCp)₂ dose=6 s, ClSc(EtCp)₂ exposure=4 s, ClSc(EtCp)₂ purge=20 s, N₂—H₂ plasma dose=20 s and N₂—H₂ plasma purge=5 s (cycle time=55 s). These process parameters were used to grow ScN #1 and ScN #2, as well as two additional films on sapphire and magnesium oxide substrates for structural and electrical characterization.

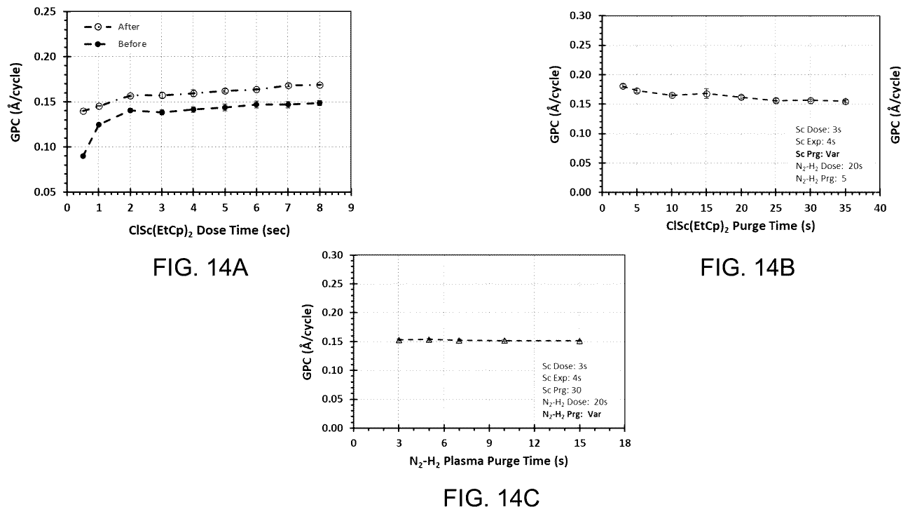

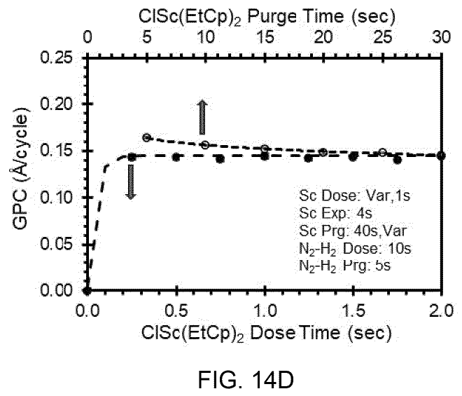

It is noted here some anomalous behavior was observed of the ClSc(EtCp)₂ precursor after aging and thermal cycling. Specifically, following a thermal cycling between 180° C. and room temperature of the chemical reservoir containing the Sc precursor, an approximately 12% increase in the GPC was observed at a substrate temperature of 215° C. This increase was compared to the same process carried out under identical conditions prior to the thermal cycling event. The modified ClSc(EtCp)₂ dose saturated at 3 s and yielded a 0.16 Å/cycle GPC, and experienced a slight 0.01 Å/cycle increase in GPC when the dose was increased to 8 s (see FIG. 14A), matching similar trends observed in the original dose saturation curves (see FIG. 12A).

To explain the increased GPC, we evaluated the effect of purge time to observe potential parasitic effects of precursor overlap during the dose sequence. No change in GPC was observed for ClSc(EtCp)₂ precursor purge times ≥25 s, while the N₂—H₂ purge time had no observed effect on the GPC between the entire tested range from 3-15 s (see FIGS. 14B-C). Subsequent investigation revealed dose saturation of the Sc precursor occurred at significantly shorter dose times indicative of improved ClSc(EtCp)₂ delivery after the thermal cycling event (FIG. 14D). We concluded that at least one of the manual isolation valves on the flow-through ampoule was in a partially closed position prior to thermally cycling, thereby limiting the conductance through the ampoule.

### Film Properties Analysis

For further ex situ analysis, ScN films were deposited on untreated 150 mm Si (100) substrates using the PEALD process parameters defined above. The average SE thicknesses determined ex situ for ScN #1 (XPS sample) and ScN #2 (XRR sample) were 25.4 and 41.9 nm, respectively. For both samples, the thickness non-uniformity (NU) was <±4% (1σ) and the refractive index (at 633 nm wavelength) was 2.3 with NU<±3% (1σ). The refractive index NU was primarily due to a higher value in the center vs. towards the outer diameter of the substrate. To confirm the SE thickness, XRR measurements were also performed at the substrate center and edge positions of ScN #2. The SE center and edge thicknesses were 40.6 and 42.3 nm; and the XRR center and edge thicknesses were 39.7 and 41.8 nm, respectively. These results demonstrate good agreement between the two measurement techniques. XRR also revealed a higher mass density at the center vs. edge positions as follows: ρ_{ctr}=3.84 g/cm³ and ρ_{edge}=3.78 g/cm³. The density values reported here are lower than the reported bulk value of 4.264 g/cm³ for single-crystal, cubic-phase ScN.

Higher mass density measured in the center is likely due to geometric factors during ScN growth that result in a higher plasma density and/or UV light emission from the ICP source centered above the substrate surface. The 1.6% increase in density at the center, however, does not fully account for the 5% increase in the refractive index observed for ScN #2, where n_{ctr}=2.40 and n_{edge}=2.28. To better understand this increase, the optical properties were more thoroughly investigated ex situ by SE at the center and edge positions of ScN #1 and ScN #2. A direct bandgap at ~2.45 eV was determined for both films at the center and edge positions, which is in good agreement with reported values in the literature.

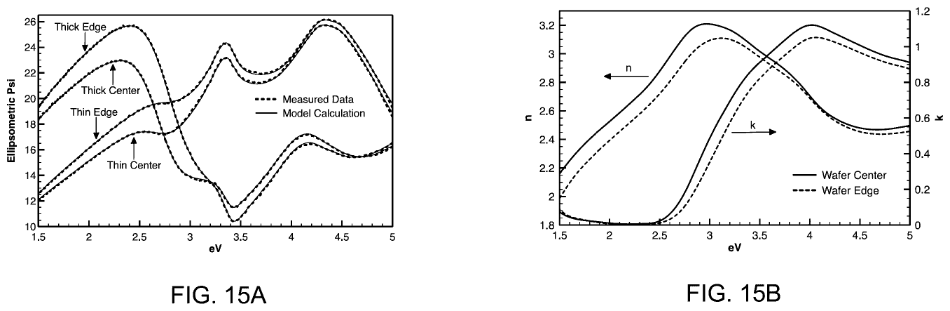

A detailed description of the measurements and the corresponding analysis is as follows. To characterize the film and overlayer thickness of ScN by PEALD, SE data were measured and analyzed over a 1.5-5 eV spectral range. Ellipsometric Psi spectra (4×) are plotted in FIG. 15A, corresponding to measurements on two ScN coated 150 mm Si (100) substrates identified as thin film (ScN #1) and thick film (ScN #2). These measurements were performed at two positions located at the center and edge of each substrate. As expected, large differences in the spectra are observed between the thin and thick films. However, significant discrepancies are also observed between the center and edge measurements. These discrepancies cannot be accounted for by simply varying the film and overlayer thicknesses in the analysis model, and suggest that the optical constants of the ScN films are significantly different between the center and edge of the substrate. To determine the ScN optical constants at the center, a multi-sample analysis was performed using the thin and thick film data sets acquired at the center of the substrate. Likewise, a multi-sample analysis was performed with the thin and thick film data sets acquired at the edge of the substrate.

To achieve a quality data fit, it is important to include an overlayer in the analysis model. XPS measurements indicated that the surface was oxidized. To incorporate the combination of roughness and oxide in the model, the optical constants of the overlayer were calculated using a 3 constituent Bruggeman effective medium approximation, assuming 50% void, 25% Sc oxide, and 25% ScN. A Kramers-Kronig consistent b-Spline was used to represent the optical constants of the ScN films in the model. The b-Spline approach avoids imposing any constraints on the shape and features in the film optical constants (which can happen when using oscillator dispersion models). The multi-sample analysis provides sufficient information content to uniquely determine the film and overlayer thicknesses, and the ScN optical constant spectra (both the index of refraction “n” and extinction coefficient “k”).

Excellent SE data fits were achieved, as seen in FIG. 15A where the model calculated curves (solid lines) lie essentially on top of the measured data (dashed lines). The good fit is also quantified by the low MSE values shown in Table 1, which also reports the resulting film and overlayer thickness values. The determined ScN optical constant spectra are shown in FIG. 15B. For both spectra, an indirect bandgap is observed at ~2.45 eV, which is agreement with previously reported values. The general shape and critical point features are also in agreement with previously published spectra, as is the increase in “k” below the bandgap (which may in part be due to free carrier “Drude” absorption). The amplitudes of the n & k spectra are significantly lower at the edge of the wafer. However, the “edge” spectra cannot be calculated by simply mixing “void” with the “center” spectra (using the Bruggeman effective medium approximation); therefore, the change in the optical constants is not simply due to a density or porosity change in the film. A follow up investigation of this phenomenon determined that the index NU correlated with continuous H₂ flow through the ICP source during ScN growth.

TABLE 1
Film thickness data

| | ScN Film | Overlayer | Index | Multi- |
|---|---|---|---|---|
| | Thickness | Thickness | at 633 | Sample Fit |
| Data Sets | (Å) | (Å) | nm | MSE |
| Thin, Center of Wafer | 225.3 | 32.6 | 2.50 | 1.727 |
| Thick, Center of Wafer | 374.2 | 56.4 | | |
| Thin, Edge of Wafer | 230.3 | 33.7 | 2.37 | 1.594 |
| Thick, Edge of Wafer | 390.1 | 57.1 | | |

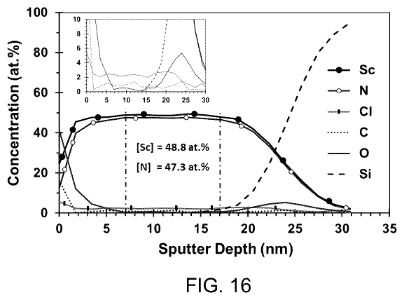

The XPS depth profile for ScN #1 is shown in FIG. 16, which contains the concentration vs. sputter depth of all major (Sc, N) and minor (Cl, C, O) components of the film. To determine the sputter depth, the SE thickness was used to convert sputter time to sputter depth. The high O and C impurity levels observed at the film surface are due to atmospheric exposure. As the Ar⁺ ions are used to sputter down into the bulk of the film, impurity levels decrease until a steady-state concentration is obtained. The native oxide interface is observed at ~24 nm, and by 30 nm depth the bulk Si substrate is reached. Bulk concentrations for ScN were determined by averaging each elemental component between 7-17 nm sputter depth, as identified in FIG. 16. The film is slightly Sc rich containing 48.8±0.5 at. % Sc and 47.3±0.4 at. % N (N:Sc=0.97±0.01). Impurities are also present in the bulk of the film including 2.3±0.2 at. % Cl, 0.9±0.3 at. % C and 0.4±0.2 at. % O. The reported uncertainties represent the ±1σ variation associated with at. % averages over the specified range (i.e., 7-17 nm sputter depth).

XPS was also performed on a sample taken from the edge of ScN #1, which showed a consistent composition with the substrate center as follows: 48.4±0.4 at. % Sc, 47.4±0.4 at. % N, 2.6±0.1 at. % Cl, 0.9±0.2 at. % C and 0.3±0.2 at. % O. The N-to-Sc ratio in this case is slightly higher (N:Sc=0.98±0.01), but within the estimated uncertainty. A summary of the XPS results are presented in Table 2. At both center and edge positions, the bulk O content measured was just above the detection limit of the instrument. When compared to other nitrides such as TiN, it has been shown that ScN films (grown by reactive magnetron sputtering techniques) are more highly susceptible to oxygen contamination. To deposit ScN with high crystalline and electrical quality, it was concluded that UHV or other environments containing low amounts of oxygen are required. The results presented in FIG. 16 demonstrate that UHP conditions provide a suitable environment for the growth of ScN by PEALD techniques.

TABLE 2
XPS depth profile results for ScN film composition

| Position | Sc (at. %) | N (at. %) | N:Sc | Cl (at. %) | C (at. %) | O (at. %) |
|---|---|---|---|---|---|---|
| Center | 48.8 ± 0.5 | 47.3 ± 0.4 | 0.97 ± 0.01 | 2.3 ± 0.2 | 0.9 ± 0.3 | 0.4 ± 0.2 |
| Edge | 48.4 ± 0.4 | 47.4 ± 0.4 | 0.98 ± 0.01 | 2.6 ± 0.1 | 0.9 ± 0.2 | 0.3 ± 0.2 |

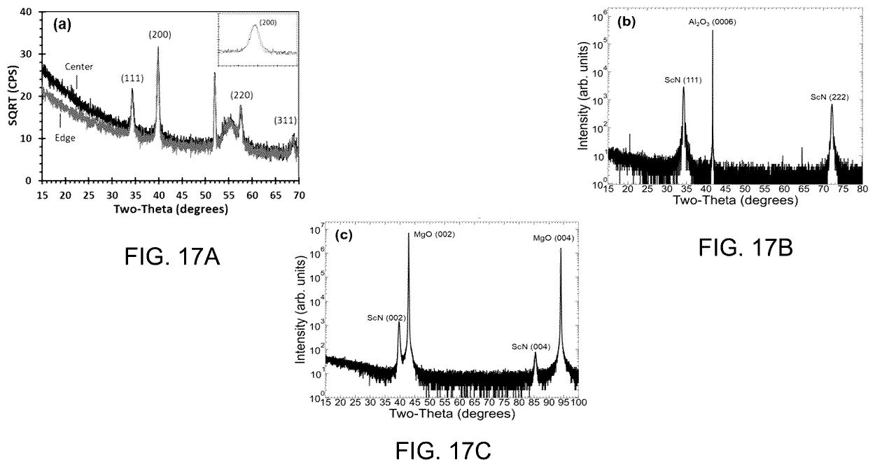

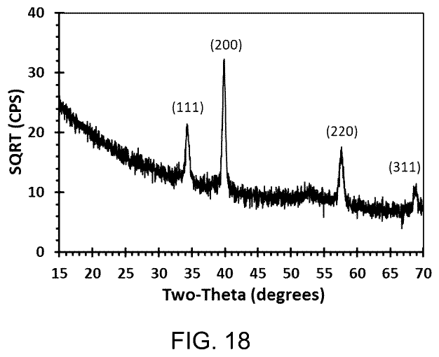

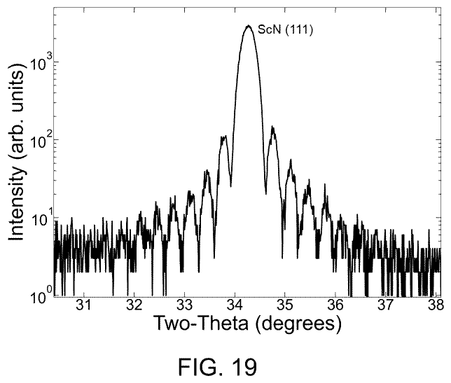

The GIXRD patterns for ScN #2 presented in FIG. 17A show (111), (200), (220) and (311) reflections matching cubic-phase ScN (PDF 04-001-1145). The narrow peak at ~52° and broad peak at ~55° are artifacts of the GIXRD method stemming from the Si substrate. These features can be eliminated and/or suppressed by rotating the substrate (see FIG. 18). Similar GIXRD patterns are observed at the center and edge positions indicative of a uniform, polycrystalline, cubic-phase structure across the 150 mm Si (100) substrate. ScN films were also deposited on Al₂O₃ (0001) and MgO (001) substrates for structural analysis, where out-of-plane XRD scans were performed to investigate signs of epitaxial growth. For ScN grown on Al₂O₃ (0001), the XRD pattern in FIG. 17B shows (111) and (222) reflections consistent with single-crystal, cubic-phase ScN. Based on the interference pattern observed for the (111) peak (see FIG. 19), the ScN film thickness was estimated at 45 nm.

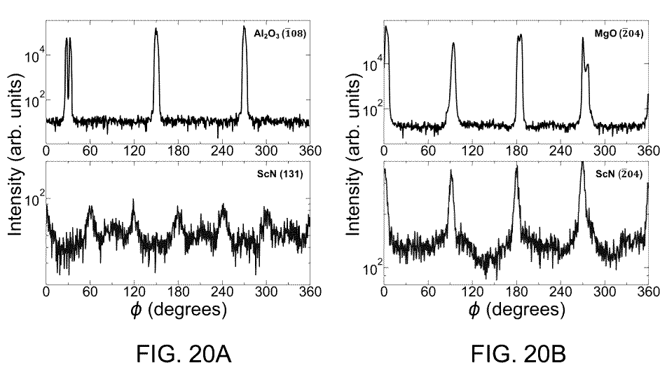

The XRD pattern for ScN deposited on MgO also indicates single-crystal, cubic-phase ScN; with the (002) and (004) reflections of the ScN film matching the underlying MgO substrate as shown in FIG. 17C. Given that both ScN and MgO crystallize in a cubic rock-salt phase (Fm3̅m), the ScN is likely grown epitaxially to the underlying MgO substrate giving rise to the shared out-of-plane (001) orientation. Based on the (002) and (004) peak positions of ScN, the out-of-plane lattice constant displays a slight elongation with a₀=4.54 Å as compared to the bulk value of a₀=4.50 Å. This is likely due to the compressive epitaxial strain imposed by the MgO substrate. When ScN is grown on the Al₂O₃ (0001) substrate, shown in FIG. 17B, the rhombohedral structure (R3̅c) displays epitaxial lattice matching with the three-fold symmetry of the cubic (111) plane forcing the observed (111) out-of-plane orientation. Additionally, based on the ScN (111) and (222) peak position, a₀=4.53 Å, slightly larger than the expected bulk value. Furthermore, phi-scans were performed (see FIGS. 20A-B) to examine the in-plane rotational symmetries and confirm the single-crystal epitaxial growth of ScN on MgO (001) and Al₂O₃ (0001). Both show the expected in-plane symmetries, with ScN on Al₂O₃ showing 6-fold symmetry due to the underlying hexagonal structure of the sapphire substrate; and ScN on MgO showing a 4-fold symmetry due to the shared cubic structure.

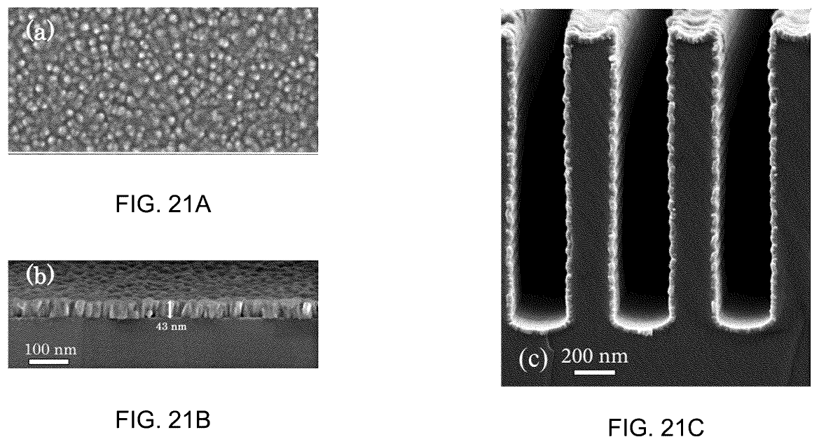

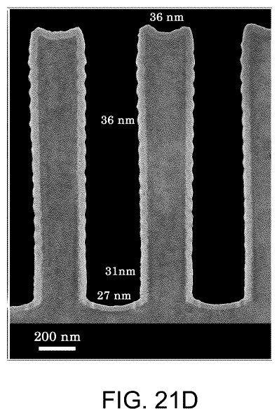

FESEM images in FIG. 21A provides a top-view and FIG. 21B provides a cross-sectional view taken from the center position of ScN #2, where columnar grains with sizes ranging from 16-28 nm are observed. Film thickness is estimated at 43 nm, which provides good agreement with the average SE thickness of 41.9 nm reported above. Film conformality was also examined by depositing ScN over 4:1 aspect ratio trench structures shown in FIG. 21C. These trenches were fabricated by RIE, where the opening measures 312 nm; the corresponding depth is 1.29 μm. The ScN film conformed well to the undulated etched Si surface, achieving a thickness of 36 nm on the top and 27 nm at the bottom of the trenches, resulting in a bottom-to-top thickness ratio of 75% (see FIG. 21D). Since the mean free path of the gas/vapor species in the reactor is more than two orders-of-magnitude larger than the trench width, the variation in thickness observed in FIG. 21C can be attributed to the ballistic transport and reaction kinetics of precursor gases/vapors, particularly plasma species, within the narrow confines of the trench structures. No attempt was made to optimize the ScN PEALD process (such as significantly increasing dose times) for improving coverage across the high aspect ratio (HAR), nm-scale features.

Electrical properties were also evaluated for the ScN films deposited on Al₂O₃ (0001) and MgO (001) substrates represented by FIG. 17B and FIG. 17C, respectively. ScN was deposited concurrently on both substrates, along with the HAR substrate shown in FIG. 21C. A small (~2 cm×2 cm) Si (100) substrate was also included as a witness sample. Film thickness determined by SE on the Si witness sample was 34.3 nm (index=2.39), which provides good agreement with the 36 nm ScN thickness measured by FESEM at the top of the HAR trench structures (see FIGS. 21C-D). However, the film thickness determined by interference fringes observed for ScN on Al₂O₃ (0001) described above (see FIG. 19), indicate 45 nm Sc thickness. This suggests a higher GPC for single-crystal vs. polycrystalline cubic-phase ScN by PEALD. Hall measurements were subsequently performed to determine average values for ScN resistivity, mobility and carrier concentrations. A summary of these results are presented in Table 3.

TABLE 3
Hall measurement results for ScN

| Substrate | Resistivity | Mobility | Carrier Conc. |
|---|---|---|---|
| Material | (mΩ · cm) | (cm²/Vs) | (cm⁻³) |
| Al₂O₃ (0001) | 13.9 | 23.5 | 2.36 × 10¹⁹ |
| MgO (001) | 1.01 | 298.0 | 2.35 × 10¹⁹ |

Density functional theory (DFT) calculations by Deng et al., Optical and transport measurement and first-principles determination of the ScN band gap, Phys. Rev. B, 91, 045104 (2015), predicted a direct band gap at 2.02 eV for intrinsic cubic-phase ScN. High quality ScN epilayers grown by HVPE, with very low levels of impurities, were reported by Oshima et al., Epitaxial growth of phase-pure ε-Ga₂O₃ by halide vapor phase epitaxy, J. Appl. Phys., 115, 153508 (2014), where the direct band gap was measured at 2.06 eV. This measured band gap is in good agreement with the calculated value of 2.02 eV by Deng. Free electron concentrations, however, ranged from 10-18 to 10-20 cm⁻³ for nominally undoped ScN films. These carrier concentrations could not be attributed to impurities, but could be related to native point defects (e.g., nitrogen vacancies) in the bulk of the ScN film. The results of the study by Deng also showed that for epitaxial layers grown by reactive magnetron sputtering, the direct band gap increased between 2.18-2.7 eV with increasing carrier concentration ranging from 1.12-12.8×1020 cm⁻³, respectively. The increase in the band gap and free electron concentration were attributed to an increase in fluorine (F) impurities serving as n-type donors. Film composition measured by Auger electron spectroscopy (AES) and XPS determined that F impurity levels ranged from below the AES-XPS detection limit to 3 at. % F. A similar relationship between the direct band gap and carrier concentration was observed by Moram et al., The effect of oxygen incorporation in sputtered scandium nitride films, Thin Solid Films, 516, 8569-8572 (2008), but the increase was attributed to O impurities. In this case, the direct band gap increased between 2.2 and 3.1 eV with carrier concentrations ranging from 1021 and 1022 cm⁻³, respectively. The effect of F, O, H and tantalum (Ta) impurities on carrier concentration in bulk cubic-phase ScN was theoretically investigated by Kumagai et al., Point Defects and p-Type Doping in ScN from First Principles, Phys. Rev. Appl., 9, 034019 (2018), which showed that these elements act as either single (O) or double n-type donors (H, F, Ta).

For PEALD ScN, the measured carrier concentrations reported in Table 3 are significantly lower than the values reported by Deng and Moram described above. However, these values are consistent with those reported by Oshima for high quality ScN epilayers grown by HVPE with very low levels of impurities. For ScN deposited epitaxially on MgO (001) by PEALD, the measured mobility of 298 cm²/Vs is also consistent with the mobility reported by Oshima at 284 cm²/Vs for films grown by HVPE on m-plane sapphire. The higher mobility reported here could be explained by the MgO (001) substrate providing a more ideal ScN growth template vs. m-plane sapphire.

### Investigation Summary

For ScN grown at 215° C. on Si (100), XPS depth profiling showed the film was slightly Sc rich containing 48.6 at. % Sc and 47.4 at. % N (N:Sc=0.97). Impurities were also present in the bulk of the film including 2.5 at. % Cl, 0.9 at. % C and 0.4 at. % O. The oxygen content measured was just above the detection limit of the XPS instrument. GIXRD measurements produced (111), (200), (220) and (311) reflections matching polycrystalline, cubic-phase ScN. For XPS and GIXRD, center and edge positions were measured on 150 mm Si substrates where similar results were obtained, thereby confirming ScN composition and structure across the wafer (elemental concentrations defined above are averages corresponding to the center and edge positions).

FESEM images revealed columnar grains with sizes ranging from 16-28 nm. ScN conformality across 4:1 aspect ratio trench structures was also imaged by FESEM which showed a bottom-to-top thickness ratio of 75%. Out-of-plane x-ray diffraction patterns indicated single-crystal, cubic-phase ScN deposited at 215° C. on sapphire (0001) and magnesium oxide (001) substrates; phi-scans confirmed epitaxial growth. ScN electrical properties were evaluated by performing Hall measurements to determine mobility, free electron concentration and resistivity. For ScN PEALD on magnesium oxide (001), the average mobility was 298 cm²/Vs with a carrier concentration of 2.35×10¹⁹ cm⁻³. The average resistivity was 1.01 mΩ·cm.

Although the invention has been described in detail for the purpose of illustration based on what is currently considered to be the most practical and preferred embodiments, it is to be understood that such detail is solely for that purpose and that the invention is not limited to the disclosed embodiments, but, on the contrary, is intended to cover modifications and equivalent arrangements that are within the spirit and scope of the appended claims. For example, it is to be understood that the present invention contemplates that, to the extent possible, one or more features of any embodiment can be combined with one or more features of any other embodiment.

The invention claimed is:

1. A method of optimizing atomic scale processing of a coated and/or etched substrate, comprising:
providing a substrate;
subjecting the substrate to atomic scale processing to produce a coated and/or etched substrate, comprising:
dosing the substrate with a precursor;
subjecting the coated and/or etched substrate to ellipsometry, comprising:
directing a beam of light with a wavelength at a surface of the coated and/or etched substrate;
polarizing the beam of light to obtain polarized light;
measuring a change in polarization of the polarized light after the polarized light reflects off of the surface of the coated and/or etched substrate to obtain sample polarization data; and
determining a film thickness and/or an optical property of the coated and/or etched substrate by comparing the sample polarization data to an ellipsometric model; and
adjusting the atomic scale processing based on the determined film thickness and/or the determined optical property, comprising:
adjusting the dosing of the precursor based on the determined film thickness and/or the determined optical property.

2. The method of claim 1, wherein the optical property is refractive index, extinction coefficient, optical bandgap, optical resistivity, optical conductivity, or a combination thereof.

3. The method of claim 1, wherein the atomic scale processing is plasma-enhanced atomic layer deposition or thermal atomic layer deposition.

4. The method of claim 1, wherein the atomic scale processing is plasma-enhanced atomic layer etching or thermal atomic layer etching.

5. The method of claim 1, wherein the ellipsometric model is a three-layer ellipsometric model comprising a silicon substrate, a native oxide layer over the silicon substrate, and a Cauchy layer over the native oxide layer.

6. The method of claim 1, wherein the substrate comprises silicon, germanium, sapphire, magnesium oxide, boron nitride, aluminum nitride, gallium nitride, or indium nitride.

7. The method of claim 1, wherein the coated and/or etched substrate comprises the substrate, and a film on the surface of the substrate.

8. The method of claim 1, further comprising:
providing the substrate on a fixture assembly in an internal volume of a reactor; and
subjecting the substrate to the atomic scale processing, comprising:
dosing the surface of the substrate with a first precursor;
purging the remaining first precursor and/or reaction byproducts from the internal volume of the reactor;
dosing the surface of the substrate with the second precursor; and
purging the remaining second precursor and/or reaction byproducts from the internal volume of the reactor.

9. The method of claim 8, further comprising purging the remaining first precursor and/or reaction byproducts and/or the remaining second precursor and/or reaction byproducts from the internal volume of the reactor while subjecting the coated and/or etched substrate to ellipsometry.

10. The method of claim 8, further comprising dosing the first precursor and/or the second precursor while subjecting the coated and/or etched substrate to ellipsometry.

11. The method of claim 1, wherein the ellipsometry is single wavelength ellipsometry, or the ellipsometry is discrete multiwavelength ellipsometry or spectroscopic ellipsometry and further comprising directing the beam of light with a plurality of wavelengths at the surface of the substrate.

12. The method of claim 1, further comprising:
performing the atomic scale processing at room temperature, or heating the substrate to a temperature in the range of from 50° C. to 400° C.

13. The method of claim 1, further comprising subjecting the coated and/or etched substrate to ellipsometry while the coated and/or etched substrate is in an atomic scale processing reactor.

14. An atomic scale processing apparatus, comprising:
a reactor having inner and outer surfaces, wherein at least a portion of the inner surfaces define an internal volume of the reactor;
a fixture assembly positioned within the internal volume of the reactor having a surface configured to hold a coated and/or etched substrate within the internal volume of the reactor;
a first precursor delivery arrangement comprising a first precursor;
a second precursor delivery arrangement comprising a second precursor; and
an ellipsometer capable of obtaining a film thickness and/or an optical property of the coated and/or etched substrate while the coated and/or etched substrate is in the internal volume of the reactor.

15. The atomic scale processing apparatus of claim 14, further comprising:
a controller configured to optimize atomic scale processing of the coated and/or etched substrate by carrying out a series of process parameter adjustments and obtaining a plurality of film thickness values and/or optical property values from the ellipsometer for each process parameter adjustment, the plurality of film thickness values and/or optical property values forming a saturation behavior of film growth, comparing the saturation behavior at each process parameter value to a threshold, and adjusting the process parameter during the atomic scale processing to the process parameter value with a saturation behavior that satisfies the threshold.

16. The atomic scale processing apparatus of claim 14, wherein the ellipsometer is a single or a discrete multiwavelength ellipsometer or a spectroscopic ellipsometer.

17. The atomic scale processing apparatus of claim 14, wherein the second precursor delivery arrangement is an inductively coupled plasma source, and wherein the second precursor comprises plasma.

18. The atomic scale processing apparatus of claim 14, wherein a temperature of the internal volume of the reactor is in the range of from room temperature to 400° C.

19. A method of optimizing atomic scale processing of a coated and/or etched substrate, comprising:
providing a substrate in an internal volume of a reactor;
subjecting the substrate to atomic scale processing to produce a coated and/or etched substrate, comprising:
dosing the substrate with a precursor; and
purging the remaining precursor and/or reaction byproducts from the internal volume of the reactor;
subjecting the coated and/or etched substrate to ellipsometry, comprising:
directing a beam of light with a wavelength at a surface of the coated and/or etched substrate;
polarizing the beam of light to obtain polarized light;
measuring a change in polarization of the polarized light after the polarized light reflects off of the surface of the coated and/or etched substrate to obtain sample polarization data; and
determining a film thickness and/or an optical property of the coated and/or etched substrate by comparing the sample polarization data to an ellipsometric model; and
adjusting the atomic scale processing based on the determined film thickness and/or the determined optical property, comprising:
adjusting the purging of the remaining precursor and/or reaction byproducts from the internal volume of the reactor based on the determined film thickness and/or the determined optical property.

20. The method of claim 19, wherein the subjecting the substrate to the atomic scale processing comprises:
dosing the surface of the substrate with a first precursor;
purging the remaining first precursor and/or reaction byproducts from the internal volume of the reactor;
dosing the surface of the substrate with the second precursor; and
purging the remaining second precursor and/or reaction byproducts from the internal volume of the reactor.

21. The method of claim 20, wherein the adjusting the atomic scale processing comprises:
adjusting the purging of the remaining first precursor and/or reaction byproducts and/or the remaining second precursor and/or reaction byproducts from the internal volume of the reactor based on the determined film thickness and/or the determined optical property.
